(19) United States
(12) Patent Application Publication
(10) Pub. No.: US 2026/0173653 A1
(43) Pub. Date: Jun. 18, 2026

(54) Display Device And Electronic Device

(71) Applicant: Samsung Display Co., Ltd., Yongin-si (KR)

(72) Inventors: Yonghee Lee, Yongin-si (KR); Kyung-Bae Kim, Yongin-si (KR); Dongwoo Kim, Yongin-si (KR); Yeonkyung Kim, Yongin-si (KR)

(73) Assignee: Samsung Display Co., Ltd., Yongin-si (KR)

(21) Appl. No.: 19/408,537

(22) Filed: Dec. 4, 2025

(30) Foreign Application Priority Data
Dec. 18, 2024 (KR) 10-2024-0190181

(51) Int. Cl. H10K 59/121; H10D 86/40; H10D 86/60; H10H 29/32; H10H 29/49; H10K 59/131

(52) U.S. Cl. CPC H10K 59/1216; H10D 86/441; H10D 86/481; H10D 86/60; H10H 29/32; H10H 29/49; H10K 59/1213; H10K 59/131

(57) ABSTRACT

Disclosed is a display device including a semiconductor substrate and a plurality of pixels disposed on the semiconductor substrate. Each of the plurality of pixels includes a light emitting element, a first transistor, a second transistor, a first capacitor, and a second capacitor. The first capacitor includes a first-first capacitor electrode and a first-second capacitor electrode spaced apart from the first-first capacitor electrode in a horizontal direction. The second capacitor includes a second-first capacitor electrode and a second-second capacitor electrode that is spaced apart from the second-first capacitor electrode in a vertical direction and that overlaps the second-first capacitor electrode in the horizontal direction.

### CROSS-REFERENCE TO RELATED APPLICATIONS

This application claims priority under 35 U.S.C. § 119 to Korean Patent Application No. 10-2024-0190181 filed on Dec. 18, 2024, in the Korean Intellectual Property Office, the disclosure of which are incorporated by reference herein in its entirety.

### TECHNICAL FIELD

Embodiments of the present disclosure described herein relate to a display device and an electronic device, and more particularly, relate to a display device and an electronic device that include a semiconductor substrate.

### BACKGROUND

Electronic devices, such as a smart phone, a notebook computer, a car navigation unit, a smart television, and the like, which provide an image to a user include a display device for displaying an image. An augmented reality device, a virtual reality device, or a video projection device may include a micro display device. To display a high-luminance image while operating at low power, the micro display device may include a silicon wafer and light emitting elements disposed on the silicon wafer.

### SUMMARY

Embodiments of the present disclosure provide a display device and an electronic device that includes a semiconductor substrate.

According to an embodiment, a display device includes a semiconductor substrate and a plurality of pixels disposed on the semiconductor substrate.

Each of the plurality of pixels includes a light emitting element, a first transistor that is disposed between a first power line and the light emitting element and that operates depending on potential of a control node, a second transistor disposed between a data line and the control node, a first capacitor connected between a first electrode of the first transistor and the control node, and a second capacitor connected between the control node and a second electrode of the first transistor.

The first capacitor includes a first-first capacitor electrode and a first-second capacitor electrode spaced apart from the first-first capacitor electrode in a horizontal direction. The second capacitor includes a second-first capacitor electrode and a second-second capacitor electrode that is spaced apart from the second-first capacitor electrode in a vertical direction and that overlaps the second-first capacitor electrode in the horizontal direction.

According to an embodiment, an electronic device includes a display panel, a frame that accommodates the display panel, and a structure on which the frame is mounted, and the display panel includes a semiconductor substrate and a plurality of pixels disposed on the semiconductor substrate.

Each of the plurality of pixels includes a light emitting element, a first transistor that is disposed between a power line and the light emitting element and that operates depending on potential of a control node, a second transistor disposed between a data line and the control node, a first capacitor connected between a first electrode of the first transistor and the control node, and a second capacitor connected between the control node and a second electrode of the first transistor.

The first capacitor includes a first-first capacitor electrode and a first-second capacitor electrode disposed on the same layer as the first-first capacitor electrode, and the second capacitor includes a second-first capacitor electrode and a second-second capacitor electrode that overlaps the second-first capacitor electrode and that is disposed on a layer different from a layer on which the second-first capacitor electrode is disposed.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to an embodiment of the present disclosure.

FIG. 2 is a sectional view of the display device according to an embodiment of the present disclosure.

FIG. 3 is a plan view of a unit pixel area according to an embodiment of the present disclosure.

FIG. 4 is a block diagram of the display device according to an embodiment of the present disclosure.

FIG. 5A is a circuit diagram of a pixel according to an embodiment of the present disclosure.

FIG. 5B is a circuit diagram of a pixel according to an embodiment of the present disclosure.

FIG. 6 is a sectional view illustrating a portion of the display device according to an embodiment of the present disclosure.

FIGS. 7A to 7G are plan views illustrating a stacking process of a circuit layer according to an embodiment of the present disclosure.

FIG. 8 is a sectional view illustrating a portion of the display device according to an embodiment of the present disclosure.

FIG. 9 is a sectional view illustrating a portion of the display device according to an embodiment of the present disclosure.

FIG. 10 is a block diagram of an electronic device according to an embodiment of the present disclosure.

FIG. 11 is an exploded perspective view of an electronic device according to an embodiment of the present disclosure.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component, part, area, layer, or portion from other components, parts, areas, layers, or portions. For example, without departing the scope and scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

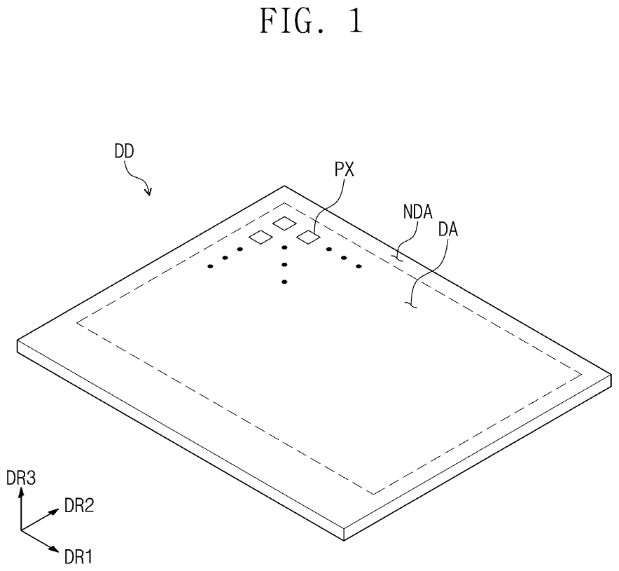

FIG. 1 is a perspective view of a display device according to an embodiment of the present disclosure.

Referring to FIG. 1, the display device DD may have a rectangular shape including long sides parallel to a first direction DR1 and short sides parallel to a second direction DR2 crossing the first direction DR1. However, embodiments are not limited thereto, and the display device DD may have various shapes such as a circular shape and a polygonal shape except for the rectangular shape. Hereinafter, a direction substantially perpendicular to a plane defined by the first direction DR1 and the second direction DR2 is defined as a third direction DR3. The expression “when viewed from above the plane” used herein may mean that it is viewed in the third direction DR3.

The display device DD may be a device activated in response to an electrical signal. The display device DD may be a display device employed in a television, a monitor, a billboard, a tablet computer, a car navigation unit, a personal computer, a notebook computer, a personal digital terminal, a game machine, a smart phone, a camera, and a wearable device. For example, the wearable device may include a virtual reality device, an augmented reality device, and a smart watch. The virtual reality device and the augmented reality device may be devices in the form of eyeglasses capable of being worn by a user. These devices are merely illustrative, and the display device DD may display an image through a display area DA in the concept of the present disclosure. A non-display area NDA may surround the display area DA. Unlike that illustrated in FIG. 1, the non-display area NDA may be disposed adjacent to only one side of the display area DA or may be omitted.

A plurality of pixels PX may be disposed in the display area DA. The pixels PX may be arranged in a matrix form. Each of the pixels PX may include a pixel circuit and a light emitting diode. All of the pixels PX may generate light of the same color. Alternatively, a plurality of pixels PX that generate light of different colors may be disposed in the display area DA. For example, first pixels that output light of a first color (or, red light), second pixels that output light of a second color (or, green light), and third pixels that output light of a third color (or, blue light) may be disposed in the display area DA.

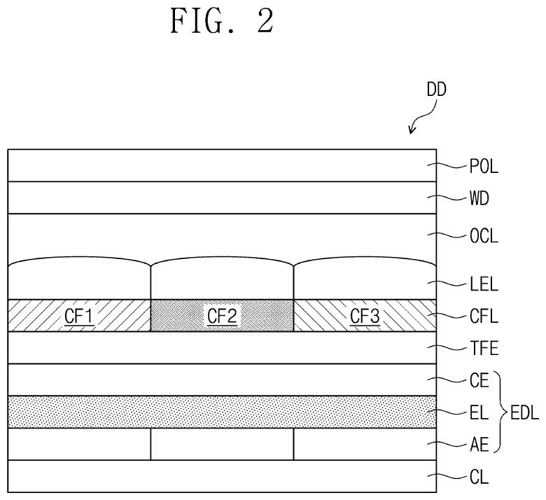

FIG. 2 is a sectional view of the display device according to an embodiment of the present disclosure.

Referring to FIG. 2, the display device DD may include a circuit layer CL, a light emitting element layer EDL, an encapsulation layer TFE, a color filter layer CFL, a lens layer LEL, an overcoat layer OCL, a window WD, and a polarization layer POL.

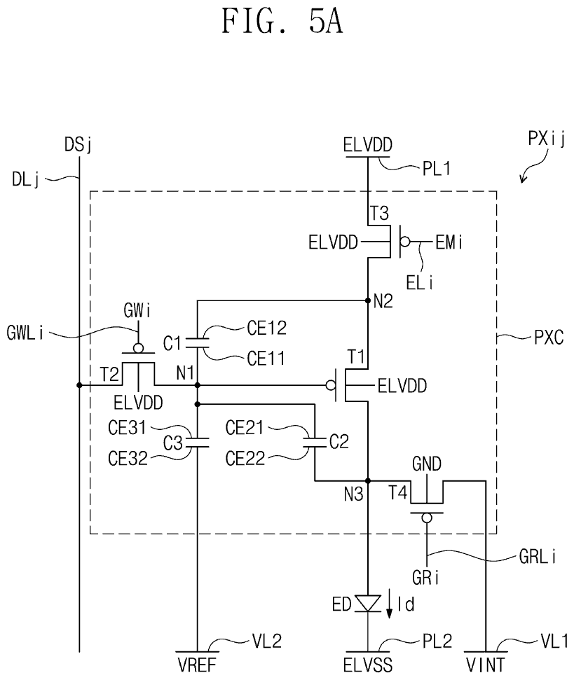

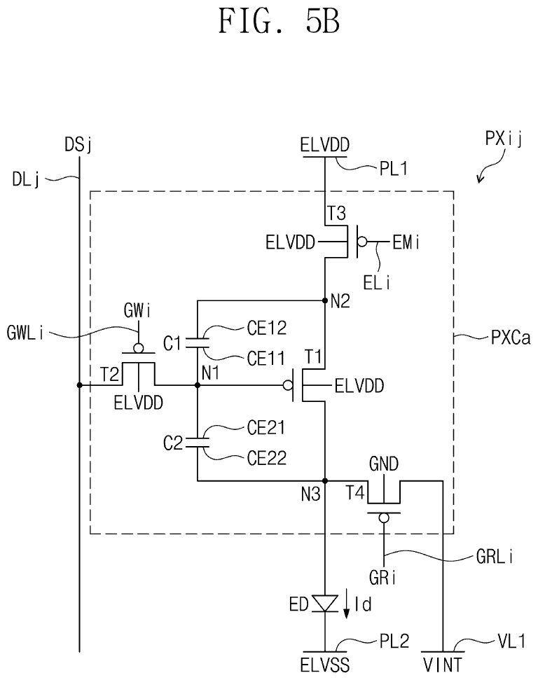

Transistors constituting a pixel circuit PXC (refer to FIG. 5A) may be formed in the circuit layer CL. The circuit layer CL may include at least one insulating layer, a conductive pattern, and a signal line. An insulating layer and a conductive layer may be formed by a process such as coating or deposition and may then be selectively subjected to patterning by performing a photolithography process a plurality of times.

The light emitting element layer EDL may be disposed on the circuit layer CL. The light emitting element lay EDL may include a first electrode AE, an emissive layer EL, and a second electrode CE. In this embodiment, the first electrode AE may be an anode, and the second electrode CE may be a cathode.

The first electrode AE may include a transparent conductive oxide pattern. The first electrode AE may be separately formed in each of the pixels PX. The transparent conductive oxide pattern may include indium tin oxide (ITO), indium zinc oxide (IZO), indium gallium zinc oxide (IGZO), zinc oxide (ZnOₓ), indium oxide (In₂O₃), or aluminum-doped zinc oxide (AZO) that facilitates hole injection. The first electrode AE may have a single-layer structure or a multi-layer structure.

The emissive layer EL may be disposed on the first electrode AE. The emissive layer EL may have a one-body shape and may be commonly provided in the pixels PX. When the emissive layer EL has a one-body shape, the emissive layer EL may provide blue light or white light. However, without being limited thereto, the emissive layer EL may be separately formed in each of the pixels PX. When the emissive layer EL is separately formed in each of the pixels PX, the emissive layer EL may emit at least one of the light of the first color, the light of the second color, and the light of the third color. The emissive layer EL may include an organic luminescent material, a quantum dot, a quantum rod, a micro-LED, or a nano-LED.

The second electrode CE may be disposed on the emissive layer EL. The second electrode CE may have a one-body shape and may be commonly disposed in the plurality of pixels PX. A common voltage may be provided to the second electrode CE, and the second electrode CE may be referred to as a common electrode.

The encapsulation layer TFE is disposed on the light emitting element layer EDL. The encapsulation layer TFE may protect the light emitting element layer EDL from foreign matter such as moisture, oxygen, and dust particles. The encapsulation layer TFE may include at least one inorganic film (hereinafter, referred to as the inorganic encapsulation film). In addition, the encapsulation layer TFE may further include at least one organic film (hereinafter, referred to as the organic encapsulation film). The encapsulation layer TFE may include an inorganic encapsulation layer, an organic encapsulation layer, and an inorganic encapsulation layer sequentially stacked one above another. However, layers constituting the encapsulation layer TFE are not limited thereto.

The color filter layer CFL may be disposed on the encapsulation layer TFE. The color filter layer CFL may include a plurality of color filters CF1, CF2, and CF3. The plurality of color filters CF1, CF2, and CF3 may include the first color filter CF1, the second color filter CF2, and the third color filter CF3. The first color filter CF1 may convert color light (e.g., blue light or the light of the third color) generated from the emissive layer EL into the light of the first color and may output the light of the first color, and the second color filter CF2 may convert the color light generated from the emissive layer EL into the light of the second color and may output the light of the second color. The third color filter CF3 may transmit the color light generated from the emissive layer EL without converting the color light and may output the light of the third color. Although not illustrated, the color filter layer CFL may further include a light blocking pattern.

The lens layer LEL may be disposed on the color filter layer CFL. The lens layer LEL may include a plurality of lens patterns. The lens patterns may be disposed to correspond to the first to third color filters CF1, CF2, and CF3, respectively, and may be spaced apart from one another.

The overcoat layer OCL may be disposed on the lens layer LEL. The overcoat layer OCL may include an optically clear material. The overcoat layer OCL may be a planarization layer and may include a flat upper surface.

The window WD may be disposed on the overcoat layer OCL. The window WD provides the outer surface of the display device DD.

The polarization layer POL may be disposed on the window WD. The polarization layer POL may have a function of blocking external light incident to the display device DD from the outside. The polarization layer POL may block a portion of the external light. In addition, the polarization layer POL may prevent reflected light generated by the reflection of the external light by the components included in the light emitting element layer EDL and the circuit layer CL from being output to the outside. That is, the polarization layer POL may be an anti-reflective layer.

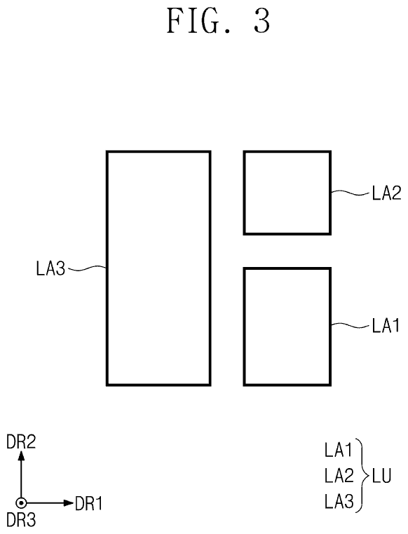

FIG. 3 is a plan view of a unit pixel area according to an embodiment of the present disclosure.

In FIG. 3, the unit pixel area LU repeatedly disposed in the display area DA of FIG. 1 is illustrated.

Referring to FIG. 3, the unit pixel area LU may include a first emissive area LA1, a second emissive area LA2, and a third emissive area LA3. A first light emitting element of the first pixel, a second light emitting element of the second pixel, and a third light emitting element of the third pixel may be disposed in the first emissive area LA1, the second emissive area LA2, and the third emissive area LA3, respectively.

Light of a first color, light of a second color, and light of a third color may be outputted through the first emissive area LA1, the second emissive area LA2, and the third emissive area LA3, respectively. When the emissive layers EL of the first to third light emitting elements are integrally formed as illustrated in FIG. 2, the first to third light emitting elements may generate light of a same color (e.g., blue light). In this case, the first color filter CF1, the second color filter CF2, and the third color filter CF3 illustrated in FIG. 2 are disposed to correspond to the first light emitting element, the second light emitting element, and the third light emitting element, respectively. Accordingly, light of the same color outputted from the first light emitting element, the second light emitting element, and the third light emitting element may be converted into the light of the first color, the light of the second color, and the light of the third color through the first color filter CF1, the second color filter CF2, and the third color filter CF3, respectively. Alternatively, when the emissive layers of the first to third light emitting elements are independently provided, the first light emitting element, the second light emitting element, and the third light emitting element may output light of the first color, light of the second color, and light of the third color, respectively.

As illustrated in FIG. 3, the first emissive area LA1, the second emissive area LA2, and the third emissive area LA3 may have different sizes. For example, the third emissive area LA3 may be larger than the first emissive area LA1, and the first emissive area LA1 may be larger than the second emissive area LA2. In this case, the first emissive area LA1 may output red light as the light of the first color, the second emissive area LA2 may output green light as the light of the second color, and the third emissive area LA3 may output blue light as the light of the third color. That is, the sizes of the emissive areas may vary depending on the efficiency of the light emitting elements.

Although the structure of the first to third emissive areas LA1, LA2, and LA3 may have a quadrangular shape as illustrated in FIG. 3, the present disclosure is not limited thereto. The shape, arrangement structure, and area ratio of the first to third emissive areas LA1, LA2, and LA3 may vary from that illustrated in FIG. 3.

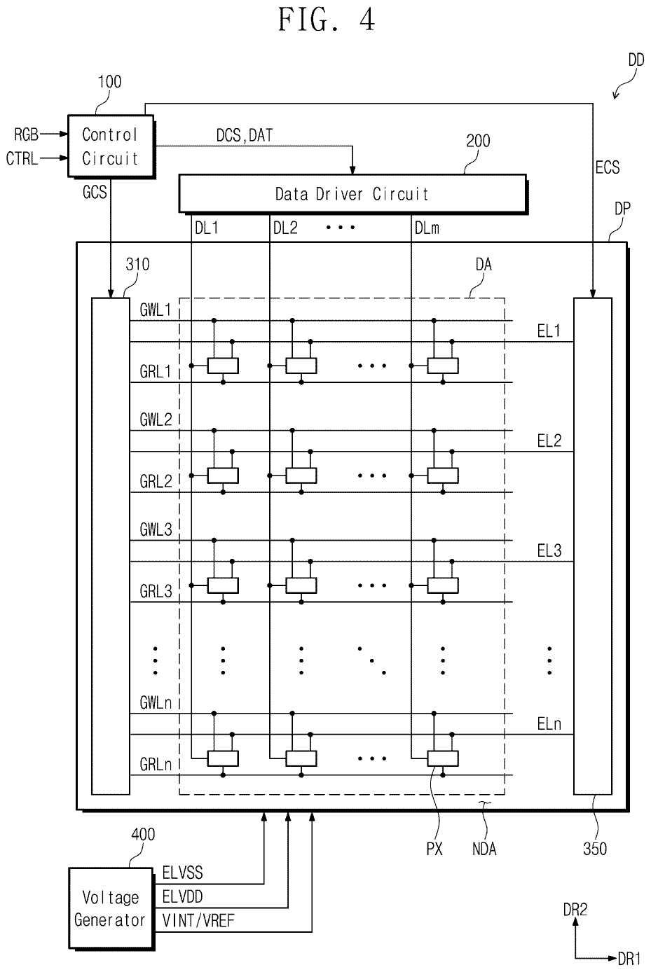

FIG. 4 is a block diagram of the display device according to an embodiment of the present disclosure.

Referring to FIG. 4, the display device DD may include a display panel DP and a panel driver. In an embodiment of the present disclosure, the panel driver may include a control circuit 100, a data driver circuit 200, a scan driver circuit 310, an emission control circuit 350, and a voltage generator 400.

The display panel DP may include a display area DA and a non-display area NDA surrounding at least a portion of the display area DA. The display panel DP may include a plurality of pixels PX disposed in the display area DA. Each of the plurality of pixels PX includes a light emitting element ED (refer to FIG. 5A) and the pixel circuit PXC (refer to FIG. 5A) that controls light emission of the light emitting element ED. The pixel circuit PXC may include at least one transistor and at least one capacitor.

The display panel DP may further include data lines DL1 to DLm, write scan lines GWL1 to GWLn, reset scan lines GRL1 to GRLn, and emission control lines EL1 to ELn. Here, m and n may be integers (or, natural numbers) of 1 or more.

The control circuit 100 receives an image signal RGB and a control signal CTRL. The control circuit 100 generates image data DAT by converting the data format of the image signal RGB according to the specification of an interface with the data driver circuit 200. The control circuit 100 outputs a first driving control signal DCS, a second driving control signal GCS, and a third driving control signal ECS.

The data driver circuit 200 receives the first driving control signal DCS and the image data DAT from the control circuit 100. The data driver circuit 200 converts the image data DAT into data signals and outputs the data signals to data lines DL1 to DLm. The data signals are analog voltages corresponding to gray level values of the image data DAT.

The scan driver circuit 310 may be disposed in the non-display area NDA of the display panel DP. The scan driver circuit 310 receives the second driving control signal GCS from the control circuit 100. The scan driver circuit 310 may be connected to the write scan lines GWL1 to GWLn and the reset scan lines GRL1 to GRLn. The scan driver circuit 310 may output write scan signals to the write scan lines GWL1 to GWLn in response to the second driving control signal GCS. The scan driver circuit 310 may output reset scan signals to the reset scan lines GRL1 to GRLn in response to the second driving control signal GCS.

The emission control circuit 350 may be disposed in the non-display area NDA of the display panel DP. The emission control circuit 350 receives the third driving control signal ECS from the control circuit 100. The emission control circuit 350 may be connected to the emission control lines EL1 to ELn. The emission control circuit 350 may output emission control signals to the emission control lines EL1 to ELn in response to the third driving control signal ECS.

The scan driver circuit 310 and the emission control circuit 350 may be integrated in the non-display area NDA of the display panel DP through the same process as the pixel circuit PXC. Each of the scan driver circuit 310 and the emission control circuit 350 may include transistors formed through the same process as the pixel circuit PXC.

The voltage generator 400 (or, the power supply circuit) generates voltages required for an operation of the display panel DP. In this embodiment, the voltage generator 400 may generate a first driving voltage ELVDD, a second driving voltage ELVSS, an initialization voltage VINT, and a reference voltage VREF.

Each of the plurality of pixels PX may be electrically connected to a corresponding one of the data lines DL1 to DLm, a corresponding one of the write scan lines GWL1 to GWLn, a corresponding one of the reset scan lines GRL1 to GRLn, and a corresponding one of the emission control lines EL1 to ELn. However, the number of signal lines connected to each of the plurality of pixels PX may vary.

Each of the plurality of pixels PX may receive the first driving voltage ELVDD, the second driving voltage ELVSS, the initialization voltage VINT, and the reference voltage VREF from the voltage generator 400. However, the reference voltage VREF may be omitted.

FIG. 5A is a circuit diagram of a pixel according to an embodiment of the present disclosure. FIG. 5B is a circuit diagram of a pixel according to an embodiment of the present disclosure.

In FIG. 5A, an equivalent circuit diagram of one pixel PXij among the plurality of pixels PX illustrated in FIG. 4 is illustrated. Since the plurality of pixels PX have the same circuit structure, description of the circuit structure of the pixel PXij may be applied to the remaining pixels, and specific description of the remaining pixels will be omitted.

Referring to FIG. 5A, the pixel PXij is connected to a j-th data line DLj among the data lines DL1 to DLm, an i-th write scan line GWLi among the write scan lines GWL1 to GWLn, an i-th reset scan line GRLi among the reset scan lines GRL1 to GRLn, and an i-th emission control line ELi among the emission control lines EL1 to ELn.

The pixel PXij includes the pixel circuit PXC and the light emitting element ED electrically connected to the pixel circuit PXC. In an embodiment of the present disclosure, the light emitting element ED may be a light emitting diode.

In this embodiment, the pixel circuit PXC may include four transistors (first to fourth transistors T1, T2, T3, and T4) and three capacitors (first to third capacitors C1, C2, and C3). Each of the first to fourth transistors T1 to T4 may be a transistor having an LTPS semiconductor layer. In an embodiment of the present disclosure, the first to fourth transistors T1 to T4 may be P-type transistors. However, the present disclosure is not limited thereto. Alternatively, the first to fourth transistors T1 to T4 may be N-type transistors. In another case, some of the first to fourth transistors T1 to T4 may be P-type transistors, and the other transistors may be N-type transistors. For example, among the first to fourth transistors T1 to T4, the first to third transistors T1 to T3 may be P-type transistors, and the fourth transistor T4 may be an N-type transistor with an oxide semiconductor as a semiconductor layer.

The i-th write scan line GWLi, the i-th reset scan line GRLi, and the i-th emission control line ELi may supply the i-th write scan signal GWi, the i-th reset scan signal GRi, and the i-th emission control signal EMi to the pixel PXij. The j-th data line DLj supplies the j-th data signal DSj to the pixel PXij.

In an embodiment of the present disclosure, the pixel PXij may be connected to a first power line PL1, a second power line PL2, a first voltage line VL1, and a second voltage line VL2. The first power line PL1 may provide the first driving voltage ELVDD to the pixel PXij, and the second power line PL2 may provide the second driving voltage ELVSS to the pixel PXij. In addition, the first voltage line VL1 may provide the initialization voltage VINT to the pixel PXij, and the second voltage line VL2 may provide the reference voltage VREF to the pixel PXij. The first voltage line VL1 may be referred to as an initialization voltage line, and the second voltage line VL2 may be referred to as a reference voltage line.

The first transistor T1 is connected between the first power line PL1, which receives the first driving voltage ELVDD, and an anode (or, a first electrode) of the light emitting element ED. The first transistor T1 may be referred to as a driving transistor. The first transistor T1 may include a first electrode, a second electrode, and a gate electrode. The gate electrode of the first transistor T1 may be connected to a first node N1 (or, a control node), the first electrode of the first transistor T1 may be connected to a second node N2, and the second electrode of the first transistor T1 may be connected to the anode of the light emitting element ED. The first electrode may be referred to as a drain of the first transistor T1, and the second electrode may be referred to as a source of the first transistor T1. The first transistor T1 may operate depending on the potential of the first node N1 to supply a driving current Id to the light emitting element ED.

The second transistor T2 is connected between the j-th data line DLj and the first node N1 and receives the i-th write scan signal GWi. The second transistor T2 may be referred to as a switching transistor. The second transistor T2 may include a first electrode connected to the j-th data line DLj, a second electrode connected to the first node N1, and a gate electrode connected to the i-th write scan line GWLi. The second transistor T2 may be turned on by the i-th write scan signal GWi received through the i-th write scan line GWLi and may apply the j-th data signal DSj provided from the j-th data line DLj to the first node N1.

The third transistor T3 is connected between the first power line PL1 and the second node N2 and receives the i-th emission control signal EMi. The third transistor T3 includes a first electrode connected to the first power line PL1, a second electrode connected with the first electrode of the first transistor T1 (that is, the second node N2), and a gate electrode connected to the i-th emission control line ELi. The third transistor T3 may be turned on or off in response to the i-th emission control signal EMi provided through the i-th emission control line ELi. The first driving voltage ELVDD may be applied to the first transistor T1 through the turned-on third transistor T3.

The fourth transistor T4 may be connected between the first voltage line VL1, which provides the initialization voltage VINT, and the anode of the light emitting element ED and may receive the i-th reset scan signal GRi. The fourth transistor T4 includes a first electrode connected with the first voltage line VL1, a second electrode connected with the second electrode of the first transistor T1 (that is, a third node N3), and a gate electrode connected to the i-th reset scan line GRLi. The third node N3 may be a node to which the second electrode of the first transistor T1, the second electrode of the fourth transistor T4, and the anode of the light emitting element ED are connected. The fourth transistor T4 may be turned on by the i-th reset scan signal GRi provided through the i-th reset scan line GRLi and may initialize (or, reset) the third node N3 (that is, the anode of the light emitting element ED) to the initialization voltage VINT.

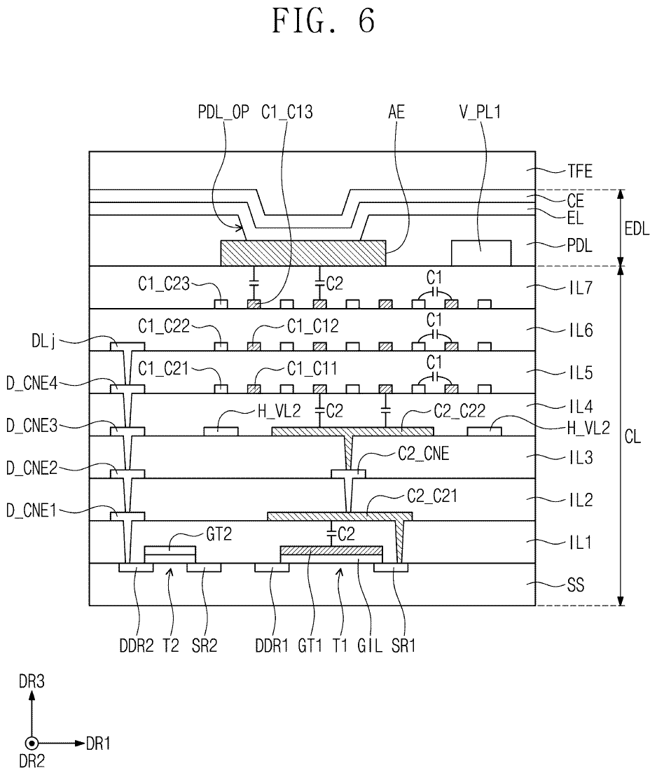

In an embodiment of the present disclosure, each of the first to fourth transistors T1 to T4 may further include a third electrode. The third electrode of each of the first to fourth transistors T1 to T4 is connected to a substrate (e.g., a semiconductor substrate SS (refer to FIG. 6)) to allow the substrate to have a constant voltage. As illustrated in FIG. 5A, the third electrodes of the first to third transistors T1 to T3 may receive the first driving voltage ELVDD, and the third electrode of the fourth transistor T4 may receive a ground voltage GND.

The first capacitor C1 may be connected between the gate electrode of the first transistor T1 (that is, the first node N1) and the first electrode of the first transistor T1 (that is, the second node N2). The first capacitor C1 includes a first-first capacitor electrode CE11 connected to the first node N1 and a first-second capacitor electrode CE12 connected to the second node N2. The first capacitor C1 may store a voltage difference between the first node N1 and the second node N2.

The second capacitor C2 may be connected between the first node N1 and the second electrode of the first transistor T1 (that is, the third node N3). The second capacitor C2 includes a second-first capacitor electrode CE21 connected to the first node N1 and a second-second capacitor electrode CE22 connected to the third node N3. The second capacitor C2 may store a voltage difference between the first node N1 and the third node N3.

The third capacitor C3 may be connected between the first node N1 and the second voltage line VL2 that provides the reference voltage VREF. The third capacitor C3 includes a third-first capacitor electrode CE31 connected to the first node N1 and a third-second capacitor electrode CE32 connected to the second voltage line VL2. The third capacitor C3 may store a voltage difference between the first node N1 and the second voltage line VL2.

The anode of the light emitting element ED is connected to the third node N3 (that is, the second electrode of the first transistor T1), and a cathode (or, a second electrode) of the light emitting element ED is connected to the second power line PL2 that provides the second driving voltage ELVSS. The second driving voltage ELVSS may have a lower voltage level than the initialization voltage VINT.

In an embodiment of the present disclosure, the maximum potential difference between the second-first capacitor electrode CE21 and the second-second capacitor electrode CE22 may be greater than the maximum potential difference between the first-first capacitor electrode CE11 and the first-second capacitor electrode CE12. In addition, the potential difference between the first driving voltage ELVDD and the initialization voltage VINT may be greater than the potential difference between the first driving voltage ELVDD and the reference voltage VREF. Accordingly, the maximum potential difference between the second-first capacitor electrode CE21 and the second-second capacitor electrode CE22 may be greater than the maximum potential difference between the third-first capacitor electrode CE31 and the third-second capacitor electrode CE32.

The pixel circuit PXC of FIG. 5A is not limited thereto. The number of transistors included in the pixel circuit PXC or the number of capacitors included in the pixel circuit PXC may be changed in various ways depending on the design of the pixel circuit PXC.

As illustrated in FIG. 5B, a pixel circuit PXCa may include four transistors (first to fourth transistors T1, T2, T3, and T4) and two capacitors (a first capacitor C1 and a second capacitor C2). That is, the pixel circuit PXCa of FIG. 5B may have a structure in which the third capacitor C3 is omitted from the pixel circuit PXC of FIG. 5A. Alternatively, the pixel circuit PXCa may have a structure in which one of the four transistors T1 to T4 is omitted or at least one transistor is added.

FIG. 6 is a sectional view illustrating a portion of the display device according to an embodiment of the present disclosure.

Referring to FIG. 6, the circuit layer CL may include the semiconductor substrate SS, at least one insulating layer IL1 to IL7, and at least one conductive pattern. Although seven insulating layers IL1 to IL7 are illustrated as an example in this embodiment, the present disclosure is not limited thereto.

The semiconductor substrate SS may be a silicon substrate, a germanium substrate, or a silicon-germanium substrate. The plurality of pixels PX (refer to FIG. 4) may be formed on the semiconductor substrate SS. The semiconductor substrate SS may include the source areas SR1 and SR2 and the drain areas DDR1 and DDR2. Each of the source areas SR1 and SR2 and the drain areas DDR1 and DDR2 may be an area doped with an impurity. The source areas SR1 and SR2 and the drain areas DDR1 and DDR2 may define the transistors T1 and T2 together with the gate electrodes GT1 and GT2 to be described below. The source areas SR1 and SR2 and the drain areas DDR1 and DDR2 may be the sources or drains of the transistors T1 and T2 depending on signal flow.

Gate insulating patterns GIL and the gate electrodes GT1 and GT2 are disposed on the semiconductor substrate SS. The gate electrodes GT1 and GT2 may include metal. The gate electrodes GT1 and GT2 are disposed to correspond to areas between the source areas SR1 and SR2 and the drain areas DDR1 and DDR2. The gate insulating patterns GIL may be disposed to correspond to the gate electrodes GT1 and GT2.

The insulating layer one IL1 may be disposed on the semiconductor substrate SS. The insulating layer one IL1 may commonly overlap the plurality of pixels PX and may cover the gate electrodes GT1 and GT2 of the transistors T1 and T2. The insulating layer one IL1 may be an inorganic layer and/or an organic layer and may have a single-layer structure or a multi-layer structure. The insulating layer one IL1 may include at least one of aluminum oxide, titanium oxide, silicon oxide, silicon nitride, silicon oxy nitride, zirconium oxide, and hafnium oxide. In this embodiment, the insulating layer one IL1 may be a single silicon oxide layer. The insulating layer one IL1 may be referred to as a third insulating layer.

A second-first sub-electrode C2_C21 may be disposed on the insulating layer one IL1. The second-first sub-electrode C2_C21 may face the gate electrode GT1 of the first transistor T1 and may form the second capacitor C2. The gate electrode GT1 of the first transistor T1 may be electrically connected to the second-first capacitor electrode CE21 (refer to FIG. 5A) and may have a one-body shape with the second-first capacitor electrode CE21. Here, one-body shape means that one physical component can incorporate or act as both the gate electrode GT1 and the second-first capacitor electrode CE21. The second-first sub-electrode C2_C21 may be a component included in the second-second capacitor electrode CE22 (refer to FIG. 5A). The second-first sub-electrode C2_C21 may be spaced apart from the gate electrode GT1 of the first transistor T1 in a vertical direction (e.g., the third direction DR3) and may partially overlap the gate electrode GT1 of the first transistor T1 in a horizontal direction (e.g., the first direction DR1 or the second direction DR2). That is, the second-first capacitor electrode CE21 and the second-second capacitor electrode CE22 may be disposed on different layers.

A contact hole that exposes the drain area DDR2 of the second transistor T2 may be provided in the insulating layer one IL1. A first data connection electrode D_CNE1 connected to the drain area DDR2 of the second transistor T2 through the contact hole may be further disposed on the insulating layer one IL1.

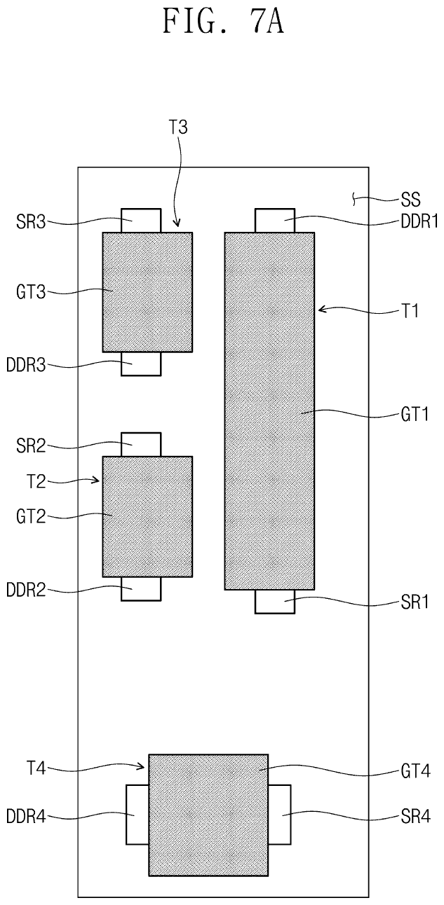

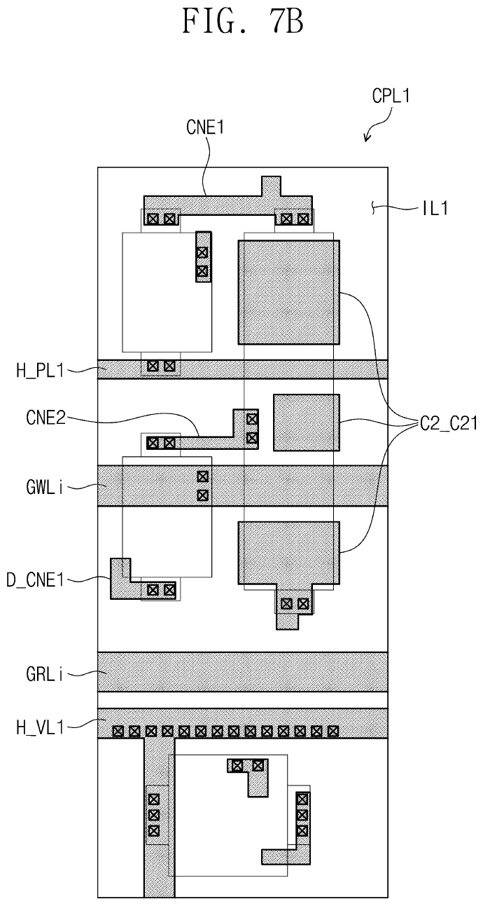

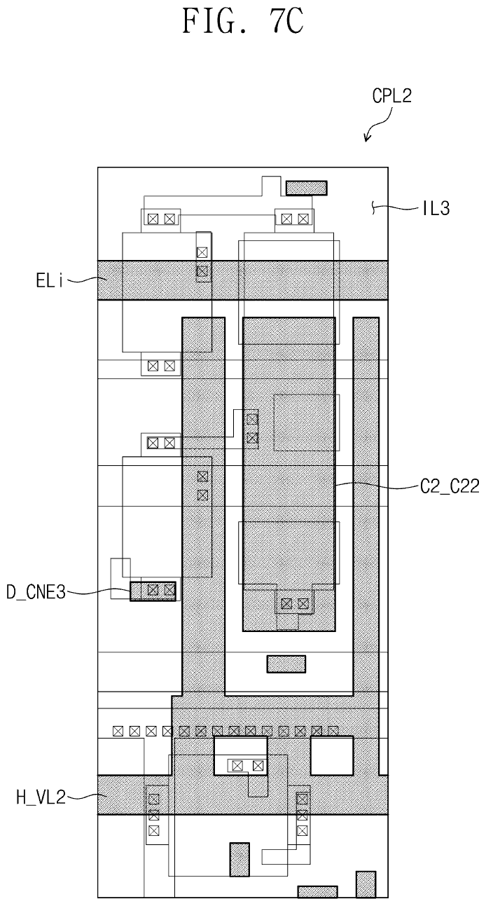

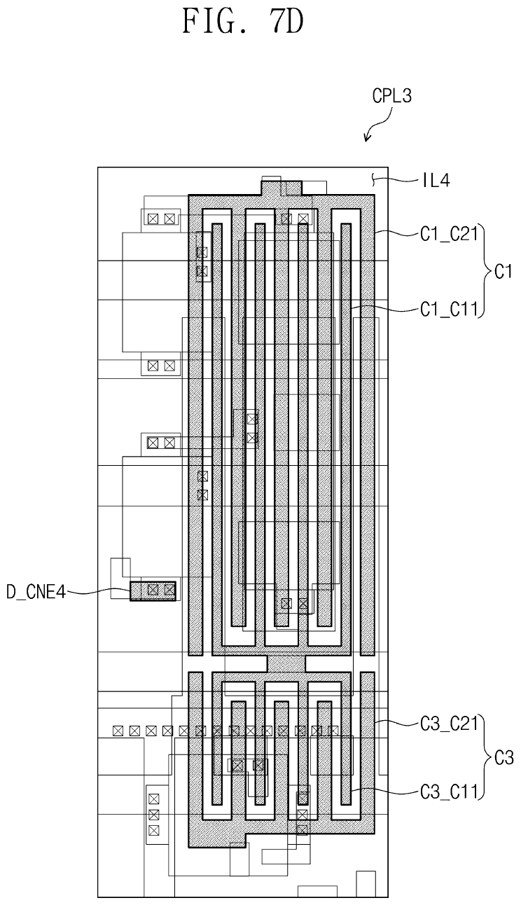

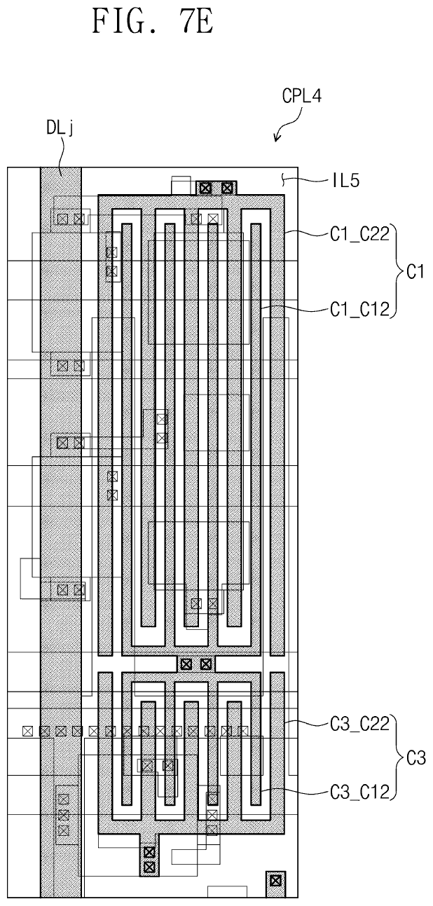

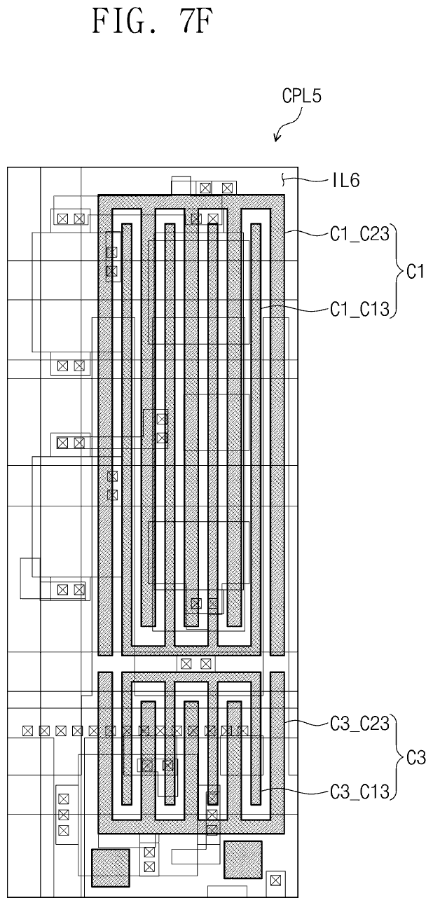

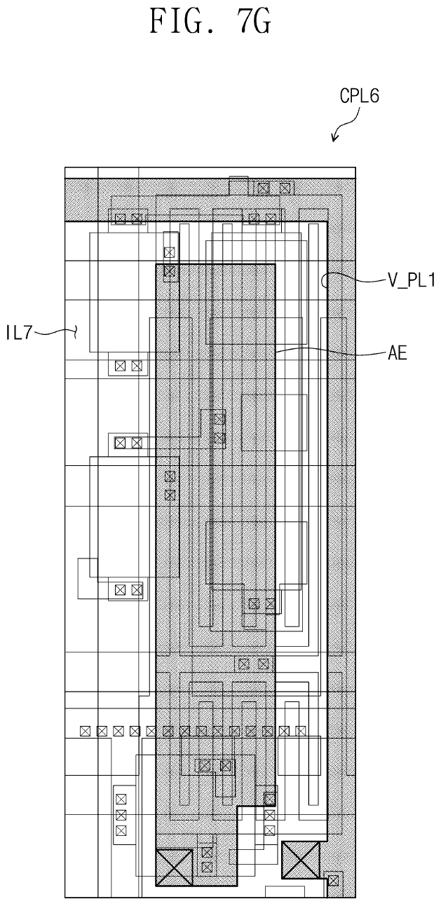

The second-first sub-electrode C2_C21 and the first data connection electrode D_CNE1 may be portions of a first conductive pattern layer CPL1 (refer to FIG. 7B).

The insulating layer two IL2 that covers the second-first sub-electrode C2_C21 and the first data connection electrode D_CNE1 is disposed on the insulating layer one IL1. The insulating layer two IL2 commonly overlaps the plurality of pixels PX. The insulating layer two IL2 may be an inorganic layer and/or an organic layer and may have a single-layer structure or a multi-layer structure. In this embodiment, the insulating layer two IL2 may be a single silicon oxide layer. The insulating layer two IL2 may be referred to as an intermediate gate insulating layer.

A capacitor connecting electrode C2_CNE is disposed on the insulating layer two IL2. A contact hole that exposes the second-first sub-electrode C2_C21 may be provided in the insulating layer two IL2. The capacitor connecting electrode C2_CNE may be connected to the second-first sub-electrode C2_C21 through the contact hole in the insulating layer two IL2.

A contact hole that exposes the first data connection electrode D_CNE1 may be further provided in the insulating layer two IL2. A second data connection electrode D_CNE2 connected to the first data connection electrode D_CNE1 through the contact hole may be further disposed on the insulating layer two IL2.

The insulating layer three IL3 that covers the capacitor connecting electrode C2_CNE and the second data connection electrode D_CNE2 is disposed on the insulating layer two IL2. The insulating layer three IL3 commonly overlaps the plurality of pixels PX. The insulating layer three IL3 may be an inorganic layer and/or an organic layer and may have a single-layer structure or a multi-layer structure. The insulating layer three IL3 may be referred to as a fourth insulating layer.

A second-second sub-electrode C2_C22 is disposed on the insulating layer three IL3. A contact hole that exposes the capacitor connecting electrode C2_CNE may be provided in the insulating layer three IL3. The second-second sub-electrode C2_C22 may be connected to the capacitor connecting electrode C2_CNE through the contact hole in the insulating layer three IL3. That is, the second-second sub-electrode C2_C22 may be electrically connected with the second-first sub-electrode C2_C21 through the capacitor connecting electrode C2_CNE.

A second horizontal voltage line H_VL2 may be further disposed on the insulating layer three IL3. The second horizontal voltage line H_VL2 may be a component included in the first voltage line VL1 (refer to FIG. 5A) to which the initialization voltage VINT (refer to FIG. 5A) is applied.

A contact hole that exposes the second data connection electrode D_CNE2 may be further provided in the insulating layer three IL3. A third data connection electrode D_CNE3 connected to the second data connection electrode D_CNE2 through the contact hole may be further disposed on the insulating layer three IL3.

The second-second sub-electrode C2_C22, the second horizontal voltage line H_VL2, and the third data connection electrode D_CNE3 may be portions of a second conductive pattern layer CPL2 (refer to FIG. 7C).

The insulating layer four IL4 that covers the second-second sub-electrode C2_C22, the second horizontal voltage line H_VL2, and the third data connection electrode D_CNE3 is disposed on the insulating layer three IL3. The insulating layer four IL4 commonly overlaps the plurality of pixels PX. The insulating layer four IL4 may be an inorganic layer and/or an organic layer and may have a single-layer structure or a multi-layer structure. The insulating layer four IL4 may be referred to as a first insulating layer.

A first-first sub-electrode C1_C11 and a first-third sub-electrode C1_C21 are disposed on the insulating layer four IL4. The first-first sub-electrode C1_C11 may be a component included in the first-first capacitor electrode CE11 (refer to FIG. 5A), and the first-third sub-electrode C1_C21 may be a component included in the first-second capacitor electrode CE12 (refer to FIG. 5A). The first-first sub-electrode C1_C11 and the first-third sub-electrode C1_C21 may be spaced apart from each other in the horizontal direction (e.g., the first direction DR1 or the second direction DR2). Accordingly, the first capacitor C1 may be formed between the first-first sub-electrode C1_C11 and the first-third sub-electrode C1_C21. The first-first capacitor electrode CE11 and the first-second capacitor electrode CE12 may be disposed on the same layer (that is, the insulating layer four IL4).

The first-first sub-electrode C1_C11 may partially overlap the second-second sub-electrode C2_C22 when viewed from above the plane and may be spaced apart from the second-second sub-electrode C2_C22 in the vertical direction (e.g., the third direction DR3). The first-first sub-electrode C1_C11 may face the second-second sub-electrode C2_C22 and may form the second capacitor C2. The first-first sub-electrode C1_C11 may be electrically connected to the second-first capacitor electrode CE21 (refer to FIG. 5A) and may have a one-body shape with the second-first capacitor electrode CE21. Here, one-body shape means that one physical component may serve as or incorporate the first-first sub-electrode C1_C11 and the second-first capacitor electrode CE21. The second-second sub-electrode C2_C22 may be a component included in the second-second capacitor electrode CE22.

A contact hole that exposes the third data connection electrode D_CNE3 may be further provided in the insulating layer four IL4. A fourth data connection electrode D_CNE4 connected to the third data connection electrode D_CNE3 through the contact hole may be further disposed on the insulating layer four IL4.

The first-first sub-electrode C1_C11, the first-third sub-electrode C1_C21, and the fourth data connection electrode D_CNE4 may be portions of a third conductive patter layer CPL3 (refer to FIG. 7D).

The insulating layer five IL5 that covers the first-first sub-electrode C1_C11, the first-third sub-electrode C1_C21, and the fourth data connection electrode D_CNE4 is disposed on the insulating layer four IL4. The insulating layer five IL5 commonly overlaps the plurality of pixels PX. The insulating layer five IL5 may be an inorganic layer and/or an organic layer and may have a single-layer structure or a multi-layer structure. The insulating layer five IL5 may be referred to as a second insulating layer.

A first-second sub-electrode C1_C12 and a first-fourth sub-electrode C1_C22 are disposed on the insulating layer five IL5. The first-second sub-electrode C1_C12 may be a component included in the first-first capacitor electrode CE11 (refer to FIG. 5A), and the first-fourth sub-electrode C1_C22 may be a component included in the first-second capacitor electrode CE12 (refer to FIG. 5A). The first-second sub-electrode C1_C12 and the first-fourth sub-electrode C1_C22 may be spaced apart from each other in the horizontal direction (e.g., the first direction DR1 or the second direction DR2). Accordingly, the first capacitor C1 may be formed between the first-second sub-electrode C1_C12 and the first-fourth sub-electrode C1_C22. The first-first capacitor electrode CE11 and the first-second capacitor electrode CE12 may be disposed on the same layer (that is, the insulating layer five IL5).

A contact hole that exposes the fourth data connection electrode D_CNE4 may be further provided in the insulating layer five IL5. The j-th data line DLj connected to the fourth data connection electrode D_CNE4 through the contact hole may be further disposed on the insulating layer five IL5. The j-th data line DLj may be electrically connected to the drain area DDR2 of the second transistor T2 through the first to fourth data connection electrodes D_CNE1 to D_CNE4.

The first-second sub-electrode C1_C12, the first-fourth sub-electrode C1_C22, and the j-th data line DLj may be portions of a fourth conductive pattern layer CPL4 (refer to FIG. 7E).

The insulating layer six IL6 that covers the first-second sub-electrode C1_C12, the first-fourth sub-electrode C1_C22, and the j-th data line DLj is disposed on the insulating layer five IL5. The insulating layer six IL6 may be referred to as a third data insulating layer.

A first-fifth sub-electrode C1_C13 and a first-sixth sub-electrode C1_C23 are disposed on the insulating layer six IL6. The first-fifth sub-electrode C1_C13 may be a component included in the first-first capacitor electrode CE11 (refer to FIG. 5A), and the first-sixth sub-electrode C1_C23 may be a component included in the first-second capacitor electrode CE12 (refer to FIG. 5A). The first-fifth sub-electrode C1_C13 and the first-sixth sub-electrode C1_C23 may be spaced apart from each other in the horizontal direction (e.g., the first direction DR1 or the second direction DR2). Accordingly, the first capacitor C1 may be formed between the first-fifth sub-electrode C1_C13 and the first-sixth sub-electrode C1_C23. The first-first capacitor electrode CE11 and the first-second capacitor electrode CE12 may be disposed on the same layer (that is, the insulating layer six IL6).

The first-fifth sub-electrode C1_C13 and the first-sixth sub-electrode C1_C23 may be portions of a fifth conductive pattern layer CPL5 (refer to FIG. 7F).

The insulating layer seven IL7 that covers the first-fifth sub-electrode C1_C13 and the first-sixth sub-electrode C1_C23 is disposed on the insulating layer six IL6. The insulating layer seven IL7 may be referred to as an anode insulating layer.

The anode AE and a mesh power line V_PL1 are disposed on the insulating layer seven IL7. The anode AE may partially overlap the first-fifth sub-electrode C1_C13 in the vertical direction (e.g., the third direction DR3). Accordingly, the second capacitor C2 may be formed between the first-fifth sub-electrode C1_C13 and the anode AE. The first-fifth sub-electrode C1_C13 may be electrically connected to the second-first capacitor electrode CE21 (refer to FIG. 5A) and may have a one-body shape with the second-first capacitor electrode CE21, i.e. one physical component may incorporate or act as both the first-fifth sub-electrode C1_C13 and the second-first capacitor electrode CE21. The anode AE may be electrically connected to the second-second capacitor electrode CE22 (refer to FIG. 5A) and may have a one-body shape with the second-second capacitor electrode CE22, i.e. one physical component may incorporate or act as both components.

The mesh power line V_PL1 may be a component included in the first power line PL1 (refer to FIG. 5A) to which the first driving voltage ELVDD (refer to FIG. 5A) is applied.

The anode AE and the mesh power line V_PL1 may be portions of a sixth conductive pattern layer CPL6 (refer to FIG. 7G).

A pixel defining layer PDL that covers the anode AE and the mesh power line V_PL1 is disposed on the insulating layer seven IL7. A pixel opening PDL_OP that exposes the anode AE is provided in the pixel defining layer PDL. The emissive layer EL is disposed on the pixel defining layer PDL and the anode AE exposed by the pixel opening PDL_OP. In this embodiment, the emissive layer EL may be commonly disposed in the plurality of pixels PX. In this case, a common emissive layer may generate white light or blue light. The cathode CE is disposed on the emissive layer EL. The cathode CE is commonly disposed in the plurality of pixels PX. The cathode CE may be sealed by the encapsulation layer TFE.

The maximum potential difference between the second-first capacitor electrode CE21 and the second-second capacitor electrode CE22 may be greater than the maximum potential difference between the first-first capacitor electrode CE11 and the first-second capacitor electrode CE12 and the maximum potential difference between the third-first capacitor electrode CE31 and the third-second capacitor electrode CE32. That is, the first capacitor C1 and the third capacitor C3 having a small internal pressure applied thereto may be formed by separating two capacitor electrodes in the horizontal direction, but the second capacitor C2 having a large internal pressure applied thereto may be formed by separating two capacitor electrodes in the vertical direction. Accordingly, a short circuit between two capacitor electrodes in the second capacitor C2 having a large internal pressure applied thereto may be prevented.

FIGS. 7A to 7G are plan views illustrating a stacking process of the circuit layer according to an embodiment of the present disclosure.

Referring to FIGS. 6 and 7A, the semiconductor substrate SS may be a silicon substrate, a germanium substrate, or a silicon-germanium substrate. The semiconductor substrate SS may be a substrate doped with a first-type impurity. The semiconductor substrate SS may include the source areas SR1 to SR4 and the drain areas DDR1 to DDR4. Each of the source areas SR1 to SR4 and the drain areas DDR1 to DDR4 may be an area doped with a second-type impurity. The second-type impurity may be different from the first-type impurity described above. For example, when the first-type impurity is a P-type impurity, the second-type impurity may be an N-type impurity. Alternatively, when the first-type impurity is an N-type impurity, the second-type impurity may be a P-type impurity. The source areas SR1 to SR4 and the drain areas DDR1 to DDR4 may be spaced apart from one another when viewed from above the plane.

The gate insulating patterns GIL and the gate electrodes GT1 to GT4 may be formed on the semiconductor substrate SS. The gate insulating patterns GIL may include silicon dioxide (SiO₂), silicon nitride (Si₃N₄), aluminum oxide (Al₂O₃), and titanium dioxide (TiO₂). The gate electrodes GT1 to GT4 may include polysilicon, titanium nitride (TiN), tungsten (W), molybdenum (Mo), and aluminum (Al). The gate insulating patterns GIL may have shapes corresponding to the shapes of the gate electrodes GT1 to GT4.

The gate electrodes GT1 to GT4 may partially overlap the corresponding source areas SR1 to SR4 and the corresponding drain areas DDR1 to DDR4, respectively, when viewed from above the plane. However, the present disclosure is not limited thereto, and the gate electrodes GT1 to GT4 may not overlap the corresponding source areas SR1 to SR4 and the corresponding drain areas DDR1 to DDR4, respectively, when viewed from above the plane.

Referring to FIGS. 6, 7A, and 7B, the insulating layer one IL1 covers the semiconductor substrate SS and the gate electrodes GT1 to GT4. The first conductive pattern layer CPL1 is formed on the insulating layer one IL1. The first conductive pattern layer CPL1 includes the second-first sub-electrode C2_C21 and the first data connection electrode D_CNE1. The second-first sub-electrode C2_C21 overlaps the gate electrode GT1 of the first transistor T1 when viewed from above the plane. Accordingly, the second capacitor C2 may be formed between the second-first sub-electrode C2_C21 and the gate electrode GT1 of the first transistor T1.

The second-first sub-electrode C2_C21 is provided in multiple parts, e.g. FIG. 7B shows three second-first sub-electrodes. The plurality of second-first sub-electrodes C2_C21 are spaced apart from one another at certain intervals. The first data connection electrode D_CNE1 is connected to the drain area DDR2 of the second transistor T2.

The first conductive pattern layer CPL1 may further include the i-th write scan line GWLi, the i-th reset scan line GRLi, a horizontal power line H_PL1, and a first horizontal voltage line H_VL1. The i-th write scan line GWLi may be connected to the gate electrode GT2 of the second transistor T2, and the i-th reset scan line GRLi may be connected to the gate electrode GT4 of the fourth transistor T4. The horizontal power line H_PL1 may receive the first driving voltage ELVDD and may constitute the first power line PL1 illustrated in FIG. 5A. The first horizontal voltage line H_VL1 may receive the initialization voltage VINT and may constitute the first voltage line VL1 illustrated in FIG. 5A.

The first conductive pattern layer CPL1 may further include a first connecting pattern CNE1 and a second connecting pattern CNE2. The first connecting pattern CNE1 may connect the source area SR3 (or, the second electrode) of the third transistor T3 and the drain area DDR1 (or, the first electrode) of the first transistor T1, and the second connecting pattern CNE2 may connect the source area SR2 (or, the second electrode) of the second transistor T2 and the gate electrode GT1 of the first transistor T1.

Referring to FIGS. 6, 7B, and 7C, the second conductive pattern layer CPL2 is formed on the insulating layer three IL3. The second conductive pattern layer CPL2 includes the second-second sub-electrode C2_C22 and the third data connection electrode D_CNE3. The second-second sub-electrode C2_C22 overlaps the gate electrode GT1 of the first transistor T1 and the second-first sub-electrode C2_C21 when viewed from above the plane. Accordingly, the second capacitor C2 may be formed between the gate electrode GT1 of the first transistor T1 and the second-first sub-electrode C2_C21.

The third data connection electrode D_CNE3 is connected to the second data connection electrode D_CNE2 through the contact hole penetrating the insulating layer three IL3.

The second conductive pattern layer CPL2 further includes the i-th emission control line ELi and the second horizontal voltage line H_VL2. The i-th emission control line ELi may be connected to the gate electrode GT3 of the third transistor T3, and the second horizontal voltage line H_VL2 may be connected to the first horizontal voltage line H_VL1 and may receive the initialization voltage VINT. The second horizontal voltage line H_VL2 may constitute the first voltage line VL1 illustrated in FIG. 5A.

Referring to FIGS. 6, 7C, and 7D, the third conductive pattern layer CPL3 is formed on the insulating layer four IL4. The third conductive pattern layer CPL3 includes the first-first sub-electrode C1_C11, the first-third sub-electrode C1_C21, a third-first sub-electrode C3_C11, a third-third sub-electrode C3_C21, and the fourth data connection electrode D_CNE4. The first-first sub-electrode C1_C11 may be a component included in the first-first capacitor electrode CE11 (refer to FIG. 5A), and the first-third sub-electrode C1_C21 may be a component included in the first-second capacitor electrode CE12 (refer to FIG. 5A). The first-first sub-electrode C1_C11 and the first-third sub-electrode C1_C21 may be spaced apart from each other in the horizontal direction (e.g., the first direction DR1 or the second direction DR2). Accordingly, the first capacitor C1 may be formed between the first-first sub-electrode C1_C11 and the first-third sub-electrode C1_C21. The first-first capacitor electrode CE11 and the first-second capacitor electrode CE12 may be disposed on the same layer (that is, the insulating layer four IL4).

The first-first sub-electrode C1_C11 may partially overlap the second-second sub-electrode C2_C22 when viewed from above the plane. Accordingly, the second capacitor C2 may be formed between the first-first sub-electrode C1_C11 and the second-second sub-electrode C2_C22.

The third-first sub-electrode C3_C11 may be a component included in the third-first capacitor electrode CE31 (refer to FIG. 5A), and the third-third sub-electrode C3_C21 may be a component included in the third-second capacitor electrode CE32 (refer to FIG. 5A). The third-first sub-electrode C3_C11 and the third-third sub-electrode C3_C21 may be spaced apart from each other in the horizontal direction (e.g., the first direction DR1 or the second direction DR2). Accordingly, the third capacitor C3 may be formed between the third-first sub-electrode C3_C11 and the third-third sub-electrode C3_C21. The third-first capacitor electrode CE31 and the third-second capacitor electrode CE32 may be disposed on the same layer (that is, the insulating layer four IL4).

The fourth data connection electrode D_CNE4 is connected to the third data connection electrode D_CNE3 through the contact hole penetrating the insulating layer four IL4.

Referring to FIGS. 6, 7D, and 7E, the fourth conductive pattern layer CPL4 is formed on the insulating layer five IL5. The fourth conductive pattern layer CPL4 includes the first-second sub-electrode C1_C12, the first-fourth sub-electrode C1_C22, a third-second sub-electrode C3_C12, a third-fourth sub-electrode C3_C22, and the j-th data line DLj. The first-second sub-electrode C1_C12 may be a component included in the first-first capacitor electrode CE11 (refer to FIG. 5A), and the first-fourth sub-electrode C1_C22 may be a component included in the first-second capacitor electrode CE12 (refer to FIG. 5A). The first-second sub-electrode C1_C12 and the first-fourth sub-electrode C1_C22 may be spaced apart from each other in the horizontal direction (e.g., the first direction DR1 or the second direction DR2). Accordingly, the first capacitor C1 may be formed between the first-second sub-electrode C1_C12 and the first-fourth sub-electrode C1_C22. The first-first capacitor electrode CE11 and the first-second capacitor electrode CE12 may be disposed on the same layer (that is, the insulating layer five IL5).

The third-second sub-electrode C3_C12 may be a component included in the third-first capacitor electrode CE31 (refer to FIG. 5A), and the third-fourth sub-electrode C3_C22 may be a component included in the third-second capacitor electrode CE32 (refer to FIG. 5A). The third-second sub-electrode C3_C12 and the third-fourth sub-electrode C3_C22 may be spaced apart from each other in the horizontal direction (e.g., the first direction DR1 or the second direction DR2). Accordingly, the third capacitor C3 may be formed between the third-second sub-electrode C3_C12 and the third-fourth sub-electrode C3_C22. The third-first capacitor electrode CE31 and the third-second capacitor electrode CE32 may be disposed on the same layer (that is, the insulating layer five IL5).

The j-th data line DLj is connected to the fourth data connection electrode D_CNE4 through the contact hole penetrating the insulating layer five IL5.

Referring to FIGS. 6, 7E, and 7F, the fifth conductive pattern layer CPL5 is formed on the insulating layer six IL6. The fifth conductive pattern layer CPL5 includes the first-fifth sub-electrode C1_C13, the first-sixth sub-electrode C1_C23, a third-fifth sub-electrode C3_C13, and a third-sixth sub-electrode C3_C23. The first-fifth sub-electrode C1_C13 may be a component included in the first-first capacitor electrode CE11 (refer to FIG. 5A), and the first-sixth sub-electrode C1_C23 may be a component included in the first-second capacitor electrode CE12 (refer to FIG. 5A). The first-fifth sub-electrode C1_C13 and the first-sixth sub-electrode C1_C23 may be spaced apart from each other in the horizontal direction (e.g., the first direction DR1 or the second direction DR2). Accordingly, the first capacitor C1 may be formed between the first-fifth sub-electrode C1_C13 and the first-sixth sub-electrode C1_C23. The first-first capacitor electrode CE11 and the first-second capacitor electrode CE12 may be disposed on the same layer (that is, the insulating layer six IL6).

The third-fifth sub-electrode C3_C13 may be a component included in the third-first capacitor electrode CE31 (refer to FIG. 5A), and the third-sixth sub-electrode C3_C23 may be a component included in the third-second capacitor electrode CE32 (refer to FIG. 5A). The third-fifth sub-electrode C3_C13 and the third-sixth sub-electrode C3_C23 may be spaced apart from each other in the horizontal direction (e.g., the first direction DR1 or the second direction DR2). Accordingly, the third capacitor C3 may be formed between the third-fifth sub-electrode C3_C13 and the third-sixth sub-electrode C3_C23. The third-first capacitor electrode CE31 and the third-second capacitor electrode CE32 may be disposed on the same layer (that is, the insulating layer six IL6).

Referring to FIGS. 6, 7F, and 7G, the sixth conductive pattern layer CPL6 is formed on the insulating layer seven IL7. The sixth conductive pattern layer CPL6 includes the anode AE and the mesh power line V_PL1. The anode AE may partially overlap the first-fifth sub-electrode C1_C13 in the vertical direction (e.g., the third direction DR3). Accordingly, the second capacitor C2 may be formed between the first-fifth sub-electrode C1_C13 and the anode AE.

The mesh power line V_PL1 may be a component included in the first power line PL1 (refer to FIG. 5A) to which the first driving voltage ELVDD (refer to FIG. 5A) is applied.

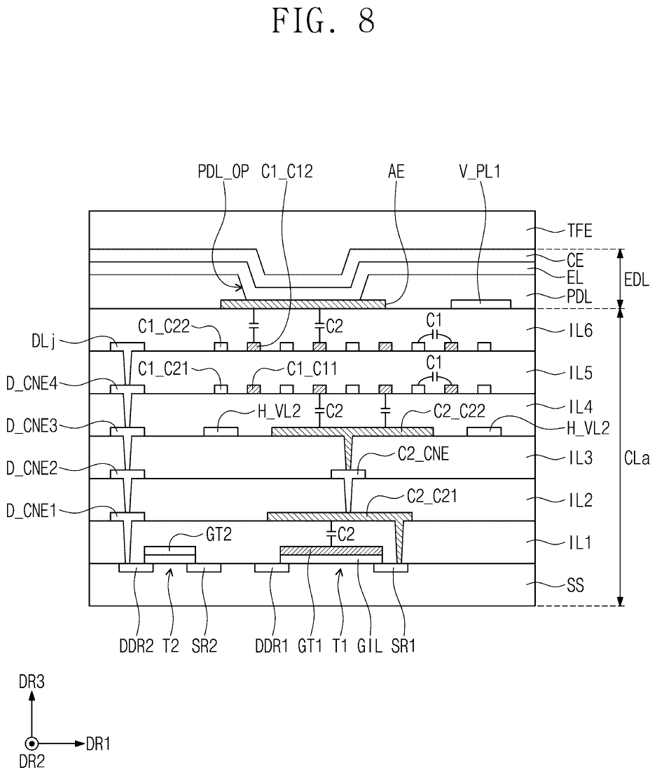

FIG. 8 is a sectional view illustrating a portion of the display device according to an embodiment of the present disclosure. Among the components illustrated in FIG. 8, components identical to the components illustrated in FIG. 6 will be assigned with identical reference numerals, and specific description thereof will be omitted.

Referring to FIG. 8, a circuit layer CLa may include a semiconductor substrate SS, at least one insulating layer IL1 to IL6, and at least one conductive pattern. Although six insulating layers IL1 to IL6 are illustrated as an example in this embodiment, the present disclosure is not limited thereto.

The insulating layer six IL6 that covers the first-second sub-electrode C1_C12 and the first-fourth sub-electrode C1_C22 is disposed on the insulating layer five IL5. The insulating layer six IL6 may be referred to as an anode insulating layer.

The anode AE and the mesh power line V_PL1 are disposed on the insulating layer six IL6. The anode AE may partially overlap the first-second sub-electrode C1_C12 in the vertical direction (e.g., the third direction DR3). Accordingly, the second capacitor C2 may be formed between the first-second sub-electrode C1_C12 and the anode AE. The first-second sub-electrode C1_C12 may be electrically connected to the second-first capacitor electrode CE21 (refer to FIG. 5A) and may have a one-body shape with the second-first capacitor electrode CE21, i.e. one physical component may incorporate or act as both components. The anode AE may be electrically connected to the second-second capacitor electrode CE22 (refer to FIG. 5A) and may have a one-body shape with the second-second capacitor electrode CE22, i.e. one physical component may incorporate or act as both components.

The mesh power line V_PL1 may be a component included in the first power line PL1 (refer to FIG. 5A) to which the first driving voltage ELVDD (refer to FIG. 5A) is applied.

The pixel defining layer PDL that covers the anode AE and the mesh power line V_PL1 is disposed on the insulating layer six IL6. The pixel opening PDL_OP that exposes the anode AE is provided in the pixel defining layer PDL. The emissive layer EL is disposed on the pixel defining layer PDL and the anode AE exposed by the pixel opening PDL_OP. In this embodiment, the emissive layer EL may be commonly disposed in the plurality of pixels PX. In this case, the common emissive layer may generate white light or blue light. The cathode CE is disposed on the emissive layer EL. The cathode CE is commonly disposed in the plurality of pixels PX. The cathode CE may be sealed by the encapsulation layer TFE.

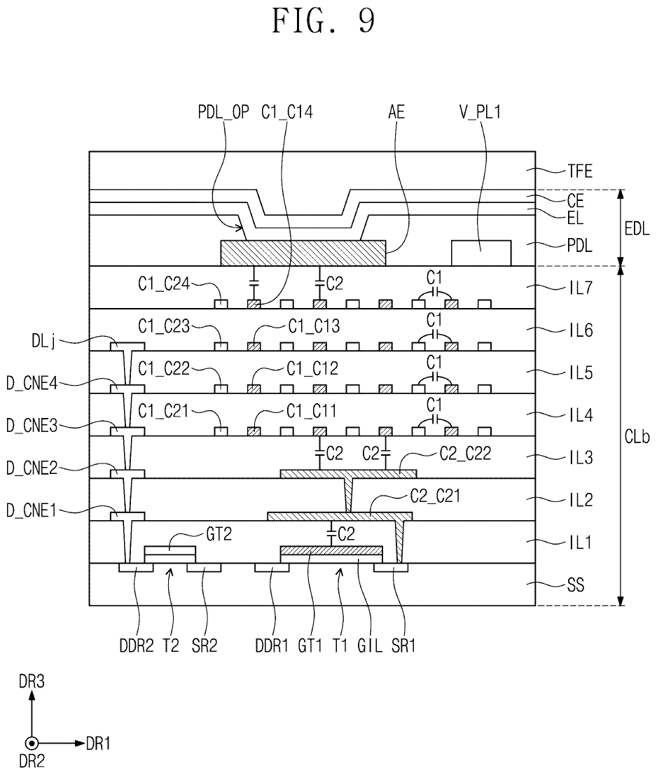

FIG. 9 is a sectional view illustrating a portion of the display device according to an embodiment of the present disclosure. Among the components illustrated in FIG. 9, components identical to the components illustrated in FIG. 6 will be assigned with identical reference numerals, and specific description thereof will be omitted.

Referring to FIG. 9, a circuit layer CLb may include a semiconductor substrate SS, at least one insulating layer IL1 to IL7, and at least one conductive pattern. Although seven insulating layers IL1 to IL7 are illustrated as an example in this embodiment, the present disclosure is not limited thereto.

The insulating layer two IL2 that covers the second-first sub-electrode C2_C21 and the first data connection electrode D_CNE1 is disposed on the insulating layer one IL1.

The second-second sub-electrode C2_C22 and the second data connection electrode D_CNE2 are disposed on the insulating layer two IL2. The contact hole that exposes the second-first sub-electrode C2_C21 may be provided in the insulating layer two IL2. The second-second sub-electrode C2_C22 may be connected to the second-first sub-electrode C2_C21 through the contact hole in the insulating layer two IL2.

The insulating layer three IL3 that covers the second-second sub-electrode C2_C22 and the second data connection electrode D_CNE2 is disposed on the insulating layer two IL2. The first-first sub-electrode C1_C11, the first-third sub-electrode C1_C21, and the third data connection electrode D_CNE3 are disposed on the insulating layer three IL3. The insulating layer three IL3 may be referred to as a first insulating layer.

The first-first sub-electrode C1_C11 may be a component included in the first-first capacitor electrode CE11 (refer to FIG. 5A), and the first-third sub-electrode C1_C21 may be a component included in the first-second capacitor electrode CE12 (refer to FIG. 5A). The first-first sub-electrode C1_C11 and the first-third sub-electrode C1_C21 may be spaced apart from each other in the horizontal direction (e.g., the first direction DR1 or the second direction DR2). Accordingly, the first capacitor C1 may be formed between the first-first sub-electrode C1_C11 and the first-third sub-electrode C1_C21.

The first-first sub-electrode C1_C11 may partially overlap the second-second sub-electrode C2_C22 when viewed from above the plane and may be spaced apart from the second-second sub-electrode C2_C22 in the vertical direction (e.g., the third direction DR3). The first-first sub-electrode C1_C11 may face the second-second sub-electrode C2_C22 and may form the second capacitor C2. The first-first sub-electrode C1_C11 may be electrically connected to the second-first capacitor electrode CE21 (refer to FIG. 5A) and may have a one-body shape with the second-first capacitor electrode CE21, i.e. one physical component may incorporate or act as both components. The second-second sub-electrode C2_C22 may be a component included in the second-second capacitor electrode CE22.

The insulating layer four IL4 that covers the first-first sub-electrode C1_C11, the first-third sub-electrode C1_C21, and the third data connection electrode D_CNE3 is disposed on the insulating layer three IL3. The insulating layer four IL4 may be referred to as a second insulating layer.

The first-second sub-electrode C1_C12, the first-fourth sub-electrode C1_C22, and the fourth data connection electrode D_CNE4 are disposed on the insulating layer four IL4. The first-second sub-electrode C1_C12 may be a component included in the first-first capacitor electrode CE11 (refer to FIG. 5A), and the first-fourth sub-electrode C1_C22 may be a component included in the first-second capacitor electrode CE12 (refer to FIG. 5A). The first-second sub-electrode C1_C12 and the first-fourth sub-electrode C1_C22 may be spaced apart from each other in the horizontal direction (e.g., the first direction DR1 or the second direction DR2). Accordingly, the first capacitor C1 may be formed between the first-second sub-electrode C1_C12 and the first-fourth sub-electrode C1_C22.

The insulating layer five IL5 covers the first-second sub-electrode C1_C12 and the first-fourth sub-electrode C1_C22, and the fourth data connection electrode D_CNE4 is disposed on the insulating layer four IL4. The insulating layer five IL5 may be referred to as a third data insulating layer.

The first-fifth sub-electrode C1_C13, the first-sixth sub-electrode C1_C23, and the j-th data line DLj are disposed on the insulating layer five IL5. The first-fifth sub-electrode C1_C13 may be a component included in the first-first capacitor electrode CE11 (refer to FIG. 5A), and the first-sixth sub-electrode C1_C23 may be a component included in the first-second capacitor electrode CE12 (refer to FIG. 5A). The first-fifth sub-electrode C1_C13 and the first-sixth sub-electrode C1_C23 may be spaced apart from each other in the horizontal direction (e.g., the first direction DR1 or the second direction DR2). Accordingly, the first capacitor C1 may be formed between the first-fifth sub-electrode C1_C13 and the first-sixth sub-electrode C1_C23.

The insulating layer six IL6 that covers the first-fifth sub-electrode C1_C13 and the first-sixth sub-electrode C1_C23 is disposed on the insulating layer five IL5. The insulating layer six IL6 may be referred to as a fourth data insulating layer.

A first-seventh sub-electrode C1_C14 and a first-eighth sub-electrode C1_C24 are disposed on the insulating layer six IL6. The first-seventh sub-electrode C1_C14 may be a component included in the first-first capacitor electrode CE11 (refer to FIG. 5A), and the first-eighth sub-electrode C1_C24 may be a component included in the first-second capacitor electrode CE12 (refer to FIG. 5A). The first-seventh sub-electrode C1_C14 and the first-eighth sub-electrode C1_C24 may be spaced apart from each other in the horizontal direction (e.g., the first direction DR1 or the second direction DR2). Accordingly, the first capacitor C1 may be formed between the first-seventh sub-electrode C1_C14 and the first-eighth sub-electrode C1_C24.

The insulating layer seven IL7 that covers the first-seventh sub-electrode C1_C14 and the first-eighth sub-electrode C1_C24 is disposed on the insulating layer six IL6. The insulating layer seven IL7 may be referred to as an anode insulating layer.

The anode AE and the mesh power line V_PL1 are disposed on the insulating layer seven IL7. The anode AE may partially overlap the first-seventh sub-electrode C1_C14 in the vertical direction (e.g., the third direction DR3). Accordingly, the second capacitor C2 may be formed between the first-seventh sub-electrode C1_C14 and the anode AE. The first-seventh sub-electrode C1_C14 may be electrically connected to the second-first capacitor electrode CE21 (refer to FIG. 5A) and may have a one-body shape with the second-first capacitor electrode CE21, i.e. one physical component may incorporate or act as both components. The anode AE may be electrically connected to the second-second capacitor electrode CE22 (refer to FIG. 5A) and may have a one-body shape with the second-second capacitor electrode CE22, i.e. one physical component may incorporate or act as both components.

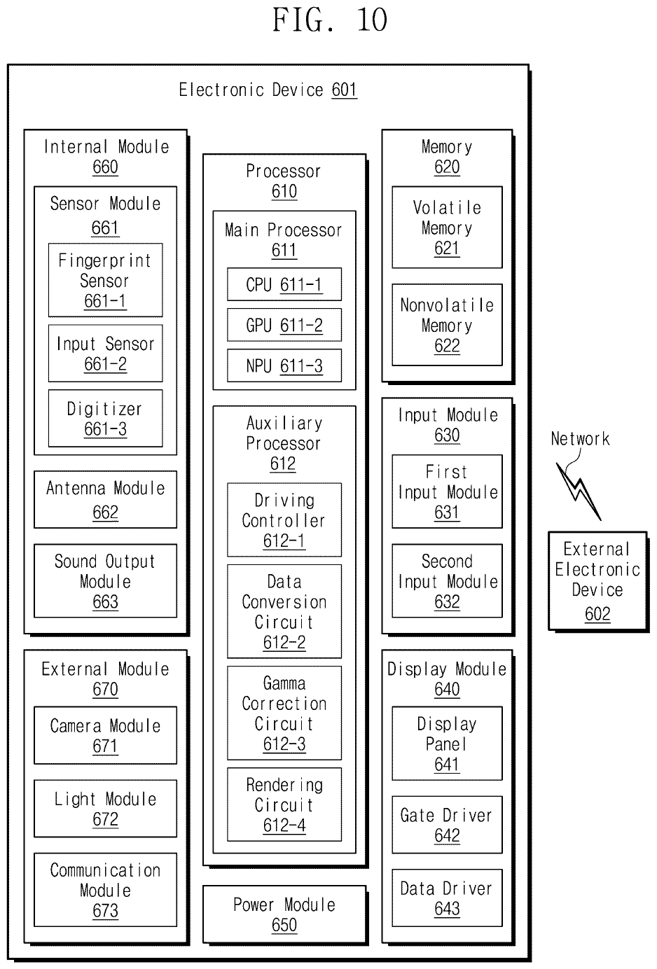

FIG. 10 is a block diagram of an electronic device according to an embodiment of the present disclosure.

Referring to FIG. 10, the electronic device 601 outputs a variety of information through a display module 640 in an operating system. When a processor 610 executes an application stored in a memory 620, the display module 640 provides a user with application information through a display panel 641.

The processor 610 obtains an external input through an input module 630 or a sensor module 661 and executes an application corresponding to the external input. For example, when the user selects a camera icon displayed in the display panel 641, the processor 610 obtains the user input through an input sensor 661-2 and activates a camera module 671. The processor 610 transfers image data corresponding to a photographed image obtained through the camera module 671 to the display module 640. The display module 640 may display an image corresponding to the photographed image through the display panel 641.

In another example, when authentication for personal information is performed in the display module 640, a fingerprint sensor 661-1 obtains the input fingerprint information as input data. The processor 610 compares the input data obtained through the fingerprint sensor 661-1 and authentication data stored in the memory 620 and executes an application depending on a comparison result. The display module 640 may display information executed depending on logic of the application, through the display panel 641.

In another example, when the user selects a music streaming icon displayed in the display module 640, the processor 610 obtains the user input through the input sensor 661-2 and activates a music streaming application stored in the memory 620. When a music play command is input to the music streaming application, the processor 610 activates a sound output module 663 and provides the user with sound information corresponding to the music play command.

The operation of the electronic device 601 has been briefly described above. Hereinafter, a configuration of the electronic device 601 will be described in detail. Some of the components of the electronic device 601 to be described later may be integrally implemented with one component, and the one component may be divided into two or more components.

Referring to FIG. 10, the electronic device 601 may communicate with an external electronic device 602 over a network (e.g., a short-range wireless communication network or a long-range wireless communication network). According to an embodiment, the electronic device 601 may include the processor 610, the memory 620, the input module 630, the display module 640, a power module 650, an internal module 660, and an external module 670. According to an embodiment, the electronic device 601 may not include at least one of the above components or may further include one or more other components. According to an embodiment, some of the above components (e.g., the sensor module 661, an antenna module 662, or the sound output module 663) may be integrated into any other component (e.g., the display module 640).

The processor 610 may execute software to control at least one component (e.g., a hardware or software component) of the electronic device 601 connected with the processor 610 and may perform various data processing or operations. According to an embodiment, as at least a part of the data processing or operations, the processor 610 may store a command or data received from any other component (e.g., the input module 630, the sensor module 661, or a communication module 673) in a volatile memory 621, may process the command or data stored in the volatile memory 621, and may store the processed data in a nonvolatile memory 622.

The processor 610 may include a main processor 611 and an auxiliary processor 612. The main processor 611 may include one or more of a central processing unit (CPU) 611-1 or an application processor (AP). The main processor 611 may further include one or more of a graphic processing unit (GPU) 611-2, a communication processor (CP), and an image signal processor (ISP). The main processor 611 may further include a neural processing unit (NPU) 611-3. The neural processing unit 611-3 may be a processor specialized for processing of an artificial intelligence model, and the artificial intelligence model may be created through machine learning. The artificial intelligence model may include a plurality of artificial neural network layers. The artificial neural network may include one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or a combination of two or more thereof, but the present disclosure is not limited thereto. Additionally or alternatively, the artificial intelligence model may include a software structure in addition to a hardware structure. At least two of the above processing units and processors may be integrally implemented with one component (e.g., a single chip), or each of the above processing units and processors may be implemented with an independent component (e.g., a plurality of chips).

The auxiliary processor 612 may include a driving controller 612-1. The driving controller 612-1 may include an interface conversion circuit and a timing control circuit. The driving controller 612-1 receives an image signal from the main processor 611 and outputs image data obtained by converting a data format of the image signal so as to be suitable for the specification of an interface with the display module 640. The driving controller 612-1 may output various kinds of control signals necessary to drive the display module 640. A configuration of the driving controller 612-1 is substantially similar to that of the control circuit 100 illustrated in FIG. 4, and therefore specific description thereof will be omitted to avoid redundancy.

The auxiliary processor 612 may further include a data conversion circuit 612-2, a gamma correction circuit 612-3, a rendering circuit 612-4, etc. The data conversion circuit 612-2 may receive image data from the driving controller 612-1; the data conversion circuit 612-2 may compensate for the image data such that an image is displayed with a desired luminance depending on a characteristic of the electronic device 601 or user settings or may convert the image data to reduce power consumption or to compensate for afterimages. The gamma correction circuit 612-3 may convert the image data or the gamma reference voltage such that an image displayed on the electronic device 601 has a desired gamma characteristic. The rendering circuit 612-4 may receive the image data from the driving controller 612-1 and may render the image data in consideration of a pixel arrangement of the display panel 641 applied to the electronic device 601. At least one of the data conversion circuit 612-2, the gamma correction circuit 612-3, and the rendering circuit 612-4 may be integrated into any other component (e.g., the main processor 611 or the driving controller 612-1). At least one of the data conversion circuit 612-2, the gamma correction circuit 612-3, and the rendering circuit 612-4 may be integrated into a data driver 643 to be described later.

The memory 620 may store various data used by at least one component (e.g., the processor 610 or the sensor module 661) of the electronic device 601 and input data or output data for commands related thereto. The memory 620 may include at least one of the volatile memory 621 and the nonvolatile memory 622.

The input module 630 may receive a command or data to be used by a component (e.g., the processor 610, the sensor module 661, or the sound output module 663) of the electronic device 601 from the outside of the electronic device 601 (e.g., the user or the external electronic device 602).

The input module 630 may include a first input module 631 to which a command or data are input from the user and a second input module 632 to which a command or data are input from the external electronic device 602. The first input module 631 may include a microphone, a mouse, a keyboard, a key (e.g., a button), or a pen (e.g., a passive pen or an active pen). The second input module 632 may support a specified protocol capable of connecting to the external electronic device 602 by wire or wirelessly. According to an embodiment, the second input module 632 may include a high definition multimedia interface (HDMI), a universal serial bus (USB) interface, a secure digital (SD) card interface, or an audio interface. The second input module 632 may include a connector capable of being physically connected with the external electronic device 602, for example, an HDMI connector, a USB connector, an SD card connector, or an audio connector (e.g., a headphone connector).

The display module 640 visually provides information to the user. The display module 640 may include the display panel 641, a gate driver 642, and the data driver 643. The display module 640 may further include a window, a chassis, and a bracket for protecting the display panel 641. The display module 640 may further include an emission driver, a voltage generator, etc. The voltage generator may output various kinds of voltages (e.g., the first driving voltage ELVDD and the second driving voltage ELVSS (refer to FIG. 4)) necessary for driving the display panel 641. Configurations of the display panel 641, the gate driver 642, the data driver 643, and the voltage generator are substantially similar to those of the display panel DP, the scan driver circuit 310, the data driver circuit 200 and the voltage generator 400 illustrated in FIG. 4, and therefore specific description will be omitted to avoid redundancy.

The power module 650 supplies power to the components of the electronic device 601. The power module 650 may include a battery that charges a power supply voltage. The battery may include a primary cell not recharged, a secondary cell rechargeable, or a fuel cell. The power module 650 may include a power management integrated circuit (PMIC). The PMIC supplies power optimized for each of the modules described above and modules to be described later. The power module 650 may include a wireless power transmission/reception member electrically connected with the battery. The wireless power transmission/reception member may include a plurality of antenna radiators that are in the form of a coil.

The electronic device 601 may further include the internal module 660 and the external module 670. The internal module 660 may include the sensor module 661, the antenna module 662, and the sound output module 663. The external module 670 may include the camera module 671, a light module 672, and the communication module 673.

The sensor module 661 may sense an input by the user's body or an input by a pen among the first input module 631 and may generate an electrical signal or a data value corresponding to the input. The sensor module 661 may include at least one of the fingerprint sensor 661-1, the input sensor 661-2, and a digitizer 661-3.

The fingerprint sensor 661-1 may generate a data value corresponding to the user's fingerprint. The fingerprint sensor 661-1 may include one of an optical fingerprint sensor or a capacitive fingerprint sensor.

The input sensor 661-2 may generate a data value corresponding to coordinate information of the input by the user's body or the input by the pen. The input sensor 661-2 generates a capacitance change due to the input as a data value. The input sensor 661-2 may sense the input by the passive pen or may exchange data with the active pen.

The input sensor 661-2 may measure a biometric signal such as blood pressure, moisture, or body fat. For example, when the user touches a part of the user's body to a sensor layer or a sensing panel and does not move during a given time period, the input sensor 661-2 may detect the biometric signal based on a change in an electric field caused by the body part and may output the information desired by the user to the display module 640.

The digitizer 661-3 may generate a data value corresponding to the coordinate information of the input by the pen. The digitizer 661-3 generates the amount of electromagnetic change by the input as a data value. The digitizer 661-3 may sense the input by the passive pen or may exchange data with the active pen.

At least one of the fingerprint sensor 661-1, the input sensor 661-2, and the digitizer 661-3 may be implemented with a sensor layer formed on the display panel 641 through a continuous process. The fingerprint sensor 661-1, the input sensor 661-2, and the digitizer 661-3 may be disposed above/on the display panel 641, and at least one of the fingerprint sensor 661-1, the input sensor 661-2, and the digitizer 661-3, for example, the digitizer 661-3 may be disposed below/under the display panel 641.

At least two of the fingerprint sensor 661-1, the input sensor 661-2, and the digitizer 661-3 may be integrally formed with one sensing panel through the same process. When they are integrally formed with one sensing panel, the sensing panel may be disposed between the display panel 641 and the window disposed above/on the display panel 641. According to an embodiment, the sensing panel may be disposed on the window, and the location of the sensing panel is not particularly limited.

At least one of the fingerprint sensor 661-1, the input sensor 661-2, and the digitizer 661-3 may be embedded in the display panel 641. That is, at least one of the fingerprint sensor 661-1, the input sensor 661-2, and the digitizer 661-3 may be simultaneously formed through a process of forming elements (e.g., a light emitting element and transistors) included in the display panel 641.

In addition, the sensor module 661 may generate an electrical signal or a data value corresponding to an internal state or an external state of the electronic device 601. The sensor module 661 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 662 may include one or more antennas to transmit or receive the signal or power to or from an external source. According to an embodiment, through an antenna suitable for a communication method, the antenna module 662 may transmit a signal to an external electronic device 602 or may receive a signal from the external electronic device 602. An antenna pattern of the antenna module 662 may be integrated with one component (e.g., the display panel 641) of the display module 640 or the input sensor 661-2.

The sound output module 663 that is a device for outputting a sound signal to the outside of the electronic device 601 may include, for example, a speaker used for general purposes such as multimedia playback or recording playback and a receiver used exclusively for receiving calls. According to an embodiment, the receiver and the speaker may be either integrally or separately implemented. A sound output pattern of the sound output module 663 may be integrated with the display module 640.

The camera module 671 may photograph a still image and a moving image. According to an embodiment, the camera module 671 may include one or more lenses, an image sensor, or an image signal processor. The camera module 671 may further include an infrared camera capable of measuring the presence or absence of the user, the location of the user, and the line of sight of the user.

The light module 672 may provide light. The light module 672 may include a light emitting diode or a xenon lamp. The light module 672 may operate in conjunction with the camera module 671 or may operate independently.

The communication module 673 may establish a wired or wireless communication channel between the electronic device 601 and the external electronic device 602 and may support communication execution through the established communication channel. The communication module 673 may include one of a wireless communication module, such as a cellular communication module, a short-range wireless communication module, or a global navigation satellite system (GNSS) communication module, and a wired communication module, such as a local area network (LAN) communication module or a power line communication module or may include all thereof. The communication module 673 may communicate with the external electronic device 602 over a short-range communication network such as Bluetooth, Wi-Fi direct, or infrared data association (IrDA) or a long-range communication network such as a cellular network, the Internet, or a computer network (e.g., a LAN or WAN). Various kinds of communication modules described above may be implemented with one chip or with separate chips, respectively.

The input module 630, the sensor module 661, the camera module 671, etc. may be used to control the operation of the display module 640 in conjunction with the processor 610.

The processor 610 outputs commands or data to the display module 640, the sound output module 663, the camera module 671, or the light module 672 based on the input data received from the input module 630. For example, the processor 610 may generate the image data corresponding to the input data applied through the mouse or the active pen and may output the image data to the display module 640; alternatively, the processor 610 may generate command data corresponding to the input data and may output the command data to the camera module 671 or the light module 672. When input data are not received from the input module 630 during a given time period, the processor 610 may switch an operating mode of the electronic device 601 to a low-power mode or a sleep mode such that the power consumption of the electronic device 601 is reduced.

The processor 610 outputs commands or data to the display module 640, the sound output module 663, the camera module 671, or the light module 672 based on the sensing data received from the sensor module 661. For example, the processor 610 may compare authentication data obtained through the fingerprint sensor 661-1 with authentication data stored in the memory 620 and may then execute an application depending on a comparison result. The processor 610 may execute a command based on the sensing data sensed by the input sensor 661-2 or the digitizer 661-3 or may output image data corresponding to the sensing data to the display module 640. When the sensor module 661 includes a temperature sensor, the processor 610 may receive temperature data associated with the measured temperature from the sensor module 661 and may further perform luminance correction on the image data based on the temperature data.

The processor 610 may receive measurement data about the presence or absence of the user, the location of the user, and the line of sight of the user from the camera module 671. The processor 610 may further perform the luminance correction on the image data based on the measurement data. For example, the processor 610 that determines the presence or absence of the user through the input from the camera module 671 may output, to the display module 640, image data whose luminance is corrected through the data conversion circuit 612-2 or the gamma correction circuit 612-3.

Some of the above components may be connected with each other through a communication scheme between peripheral devices, for example, a bus, a general purpose input/output (GPIO), a serial peripheral interface (SPI), a mobile industry processor interface (MIPI), or an ultra path interconnect (UPI) link and may exchange signals (e.g., commands or data). The processor 610 may communicate with the display module 640 through a given interface. For example, one of the communication methods described above may be used, and the present disclosure is not limited thereto.

The electronic device 601 according to various embodiments of the present disclosure may be implemented as various types of devices. The electronic device 601 may include, for example, at least one of a portable communication device (e.g., a smart phone), a computer device, a portable multimedia device, a portable medical device, a camera, a wearable device, and home appliances. The electronic device 601 according to an embodiment of the present disclosure is not limited to the above devices.

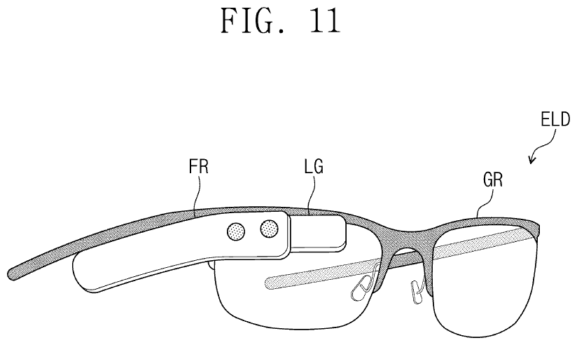

FIG. 11 is an exploded perspective view of an electronic device according to an embodiment of the present disclosure.

In FIG. 11, augmented reality (AR) glasses are illustrated as an example of a wearable device. The electronic device ELD may include the glasses GR and a frame FR mounted on the glasses GR. The frame FR may accommodate the display panel 641 described with reference to FIG. 10 or may accommodate other modules described with reference to FIG. 10. A light guide LG that guides an image generated from the display panel 641 may be mounted on the frame FR.

The glasses GR may be worn on a user's head. Since the augmented reality (AR) glasses are described as an example of a wearable device in this embodiment, the structure on which the frame FR is mounted is described as the glasses. The structure may be changed depending on the type of wearable device. In addition, the structure may be omitted depending on the type of the electronic device ELD.

According to the present disclosure, the first capacitor and the third capacitor having a small internal pressure applied thereto may be formed by separating two capacitor electrodes in the horizontal direction, but the second capacitor having a large internal pressure applied thereto may be formed by separating two capacitor electrodes in the vertical direction. Accordingly, a short circuit between two capacitor electrodes in the second capacitor having a large internal pressure applied thereto may be prevented.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a semiconductor substrate; and
a plurality of pixels disposed on the semiconductor substrate,
wherein each of the plurality of pixels comprises:
a light emitting element;
a first transistor electrically connected to a first power line and the light emitting element and configured to operate depending on potential of a control node;
a second transistor electrically connected to a data line and the control node;
a first capacitor electrically connected to a first electrode of the first transistor and the control node; and
a second capacitor electrically connected to the control node and a second electrode of the first transistor,
wherein the first capacitor comprises:
a first-first capacitor electrode; and
a first-second capacitor electrode spaced apart from the first-first capacitor electrode in a horizontal direction, and
wherein the second capacitor comprises:
a second-first capacitor electrode; and
a second-second capacitor electrode spaced apart from the second-first capacitor electrode in a vertical direction and positioned to overlap the second-first capacitor electrode.

2. The display device of claim 1, wherein the first-first capacitor electrode and the first-second capacitor electrode are disposed on a same insulating layer, and
wherein the second-first capacitor electrode and the second-second capacitor electrode are disposed on different insulating layers.

3. The display device of claim 1, wherein the second-first capacitor electrode is electrically connected with the first-first capacitor electrode, and
wherein the second-second capacitor electrode is electrically connected with an anode of the light emitting element.

4. The display device of claim 1, wherein each of the plurality of pixels further comprises a third capacitor connected to the control node and a reference voltage line.

5. The display device of claim 4, wherein the third capacitor comprises:
a third-first capacitor electrode electrically connected with the first-first capacitor electrode; and
a third-second capacitor electrode spaced apart from the third-first capacitor electrode in the horizontal direction and connected to the reference voltage line.

6. The display device of claim 5, wherein the third-first capacitor electrode and the third-second capacitor electrode are disposed on a same insulating layer.

7. The display device of claim 1, wherein the first-first capacitor electrode comprises:
a first-first sub-electrode disposed on a first insulating layer; and
a first-second sub-electrode disposed on a second insulating layer, the second insulating layer covering the first-first sub-electrode, the first-second sub-electrode positioned to overlap the first-first sub-electrode, and
wherein the first-second capacitor electrode comprises:
a first-third sub-electrode disposed on the first insulating layer and spaced apart from the first-first sub-electrode in the horizontal direction; and
a first-fourth sub-electrode disposed on the second insulating layer and positioned to overlap the first-third sub-electrode, the first-fourth sub-electrode spaced apart from the first-second sub-electrode in the horizontal direction.

8. The display device of claim 7, wherein the second-second capacitor electrode comprises:
a second-first sub-electrode disposed on a third insulating layer, the third insulating layer covering a gate electrode of the first transistor, the second-first sub-electrode positioned to partially overlap the gate electrode; and
a second-second sub-electrode disposed on a fourth insulating layer and positioned to overlap the first-first sub-electrode.

9. The display device of claim 8, wherein the second-first sub-electrode is electrically connected with the second-second sub-electrode through a capacitor connecting electrode disposed on an intermediate gate insulating layer positioned between the third insulating layer and the fourth insulating layer.

10. The display device of claim 9, wherein the first-first capacitor electrode further comprises a first-fifth sub-electrode disposed on a fifth insulating layer, the fifth insulating layer covering the first-second sub-electrode and the first-fourth sub-electrode, the first-fifth sub-electrode positioned to overlap the first-second sub-electrode, and
wherein the first-second capacitor electrode further comprises a first-sixth sub-electrode disposed on the fifth insulating layer and positioned to overlap the first-fourth sub-electrode, the first-sixth sub-electrode spaced apart from the first-fifth sub-electrode in the horizontal direction.

11. The display device of claim 10, wherein the first-first capacitor electrode further comprises a first-seventh sub-electrode disposed on a sixth insulating layer, the sixth insulating layer covering the first-fifth sub-electrode and the first-sixth sub-electrode, the first-seventh sub-electrode positioned to overlap the first-fifth sub-electrode, and
wherein the first-second capacitor electrode further comprises a first-eighth sub-electrode disposed on the sixth insulating layer and positioned to overlap the first-sixth sub-electrode, the first-eighth sub-electrode spaced apart from the first-seventh sub-electrode in the horizontal direction.

12. The display device of claim 10, wherein the light emitting element comprises an anode, the anode disposed on a seventh insulating layer, the seventh insulating layer covering the first-fifth sub-electrode and the first-sixth sub-electrode, the anode partially overlapping the first-fifth sub-electrode to form the second capacitor.

13. The display device of claim 7, wherein the light emitting element comprises an anode, the anode disposed on a sixth insulating layer, the sixth insulating layer covering the first-second sub-electrode and the first-fourth sub-electrode, the anode overlapping the first-second sub-electrode to form the second capacitor.

14. The display device of claim 13, wherein the second-second capacitor electrode comprises:
a second-first sub-electrode disposed on a third insulating layer that covers a gate electrode of the first transistor, the second-first sub-electrode positioned to partially overlap the gate electrode; and
a second-second sub-electrode disposed on a fourth insulating layer and positioned to overlap the first-first sub-electrode.

15. The display device of claim 14, wherein the second-first sub-electrode is electrically connected with the second-second sub-electrode through a capacitor connecting electrode disposed on an intermediate gate insulating layer positioned between the third insulating layer and the fourth insulating layer.

16. The display device of claim 1, wherein a maximum potential difference between the second-first capacitor electrode and the second-second capacitor electrode is greater than a maximum potential difference between the first-first capacitor electrode and the first-second capacitor electrode.

17. The display device of claim 1, wherein each of the plurality of pixels further comprises:
a third transistor electrically connected to the first power line and the first electrode of the first transistor;
a fourth transistor electrically connected to an initialization voltage line and the second electrode of the first transistor; and
a third capacitor electrically connected to the control node and a reference voltage line.

18. The display device of claim 17, wherein a first driving voltage is applied to the first power line,
wherein an initialization voltage is applied to the initialization voltage line,
wherein a reference voltage is applied to the reference voltage line, and
wherein a potential difference between the first driving voltage and the initialization voltage is greater than a potential difference between the first driving voltage and the reference voltage.

19. The display device of claim 18, wherein the light emitting element comprises a cathode, the cathode connected to a second power line, and
wherein a second driving voltage having a lower voltage level than the initialization voltage is applied to the second power line.

20. An electronic device comprising:
a display panel;
a frame configured to accommodate the display panel; and
a structure on which the frame is mounted,
wherein the display panel comprises:
a semiconductor substrate; and
a plurality of pixels disposed on the semiconductor substrate,
wherein each of the plurality of pixels comprises:
a light emitting element;
a first transistor electrically connected a power line and the light emitting element and configured to operate depending on potential of a control node;
a second transistor electrically connected to a data line and the control node;
a first capacitor electrically connected to a first electrode of the first transistor and the control node; and
a second capacitor electrically connected to the control node and a second electrode of the first transistor,
wherein the first capacitor comprises:
a first-first capacitor electrode; and
a first-second capacitor electrode disposed on a same layer as the first-first capacitor electrode, and
wherein the second capacitor comprises:
a second-first capacitor electrode; and
a second-second capacitor electrode disposed on a layer different from a layer on which the second-first capacitor electrode is disposed, the second-second capacitor electrode positioned to overlap the second-first capacitor electrode.
